(19) United States
(12) Patent Application Publication
(10) Pub. No.: US 2023/0225163 A1
(43) Pub. Date: Jul. 13, 2023

(54) DISPLAY PANEL AND DISPLAY APPARATUS INCLUDING THE SAME

(71) Applicant: Samsung Display Co., Ltd., Yongin-Si (KR)

(72) Inventors: Jisun Kim, Yongin-si (KR); Youngwan Seo, Yongin-si (KR); Kyunghoe Lee, Yongin-si (KR); Keunhee Choi, Yongin-si (KR)

(21) Appl. No.: 18/093,203

(22) Filed: Jan. 4, 2023

(30) Foreign Application Priority Data
Jan. 10, 2022 (KR) 10-2022-0003619

(51) Int. Cl. H10K 59/131; H10K 59/121

(52) U.S. Cl. CPC H10K 59/131; H10K 59/1213; H10K 59/1216

(57) ABSTRACT

A display panel of the present disclosure includes a substrate, a plurality of main pixel circuits, a plurality of first auxiliary pixel circuits, a first data line, a second data line, and a first scan line. The substrate includes a main display area and a first strip portion extending from the main display area in a first direction. The plurality of main pixel circuits are arranged in a matrix in the main display area. The plurality of first auxiliary pixel circuits are arranged in a line in the first direction in the first strip portion. The first data line is connected to first main pixel circuits in a first column and (1-1)th auxiliary pixel circuits. The second data line is connected to second main pixel circuits in a second column and (1-2)th auxiliary pixel circuits. The first scan line is connected to one of the (1-1)th auxiliary pixel circuits and one of the (1-2)th auxiliary pixel circuits. The plurality of first auxiliary pixel circuits includes the (1-1)th auxiliary pixel circuits. The plurality of first auxiliary pixel circuits includes the (1-2)th auxiliary pixel circuits.

### CROSS-REFERENCE TO RELATED APPLICATION

This application is based on and claims priority under 35 U.S.C. § 119 to Korean Patent Application No. 10-2022-0003619, filed on Jan. 10, 2022, in the Korean Intellectual Property Office, the disclosure of which is incorporated by reference herein in its entirety.

### BACKGROUND

### 1. Field

The present disclosure relates to a display panel and a display apparatus including the display panel, and more particularly, to a display panel in which a display area is extended such that an image may also be displayed in side and corner areas and a display apparatus including the display panel.

### 2. Description of the Related Art

Recently, the design of display apparatuses has been diversified. For example, curved display apparatuses, foldable display apparatuses, and rollable display apparatuses have been developed. Also, the display area thereof has been expanded and the non-display area thereof has been reduced. Accordingly, various methods have been derived to design the shape of display apparatuses.

### SUMMARY

One or more embodiments of the present disclosure may include a display panel in which a display area is extended such that an image may also be displayed in a corner area and a display apparatus including the display panel. However, these embodiments are merely examples and the scope of the disclosure is not limited thereto.

Additional aspects will be set forth in part in the description which follows and, in part, will be apparent from the description, or may be learned by practice of the presented embodiments of the disclosure.

According to one or more embodiments, a display panel includes a substrate including a main display area and a first strip portion extending from the main display area in a first direction, a plurality of main pixel circuits arranged in a matrix in the main display area, a plurality of first auxiliary pixel circuits arranged in a line in the first direction in the first strip portion, a first data line connected to first main pixel circuits in a first column among the plurality of main pixel circuits and (1-1)th auxiliary pixel circuits, a second data line connected to second main pixel circuits in a second column among the plurality of main pixel circuits and (1-2)th auxiliary pixel circuits, and a first scan line connected to one of the (1-1)th auxiliary pixel circuits and one of the (1-2)th auxiliary pixel circuits, wherein the plurality of first auxiliary pixel circuits includes the (1-1)th auxiliary pixel circuits, and wherein the plurality of first auxiliary pixel circuits includes the (1-2)th auxiliary pixel circuits.

According to an embodiment, the substrate may further include a second strip portion extending from the main display area in a second direction intersecting with the first direction, and the display panel may further include a plurality of second auxiliary pixel circuits arranged in a line in the second direction in the second strip portion, a third data line connected to third main pixel circuits in a third column among the plurality of main pixel circuits and (2-1)th auxiliary pixel circuits that are some of the plurality of second auxiliary pixel circuits, a fourth data line connected to fourth main pixel circuits in a fourth column among the plurality of main pixel circuits and (2-2)th auxiliary pixel circuits that are some of the plurality of second auxiliary pixel circuits, and a second scan line connected to one of the (2-1)th auxiliary pixel circuits and one of the (2-2)th auxiliary pixel circuits, wherein the plurality of second auxiliary pixel circuits includes the (2-1)th auxiliary pixel circuits, and wherein the plurality of second auxiliary pixel circuits includes the (2-2)th auxiliary pixel circuits.

According to an embodiment, the first scan line may be configured to transmit a first scan signal, and the second scan line may be configured to transmit a second scan signal substantially synchronized with the first scan signal.

According to an embodiment, the first scan line may be configured to transmit a first scan signal, and the second scan line may be configured to transmit a second scan signal that is later than the first scan signal by “n” horizontal scan periods, where “n” is a natural number.

According to an embodiment, the substrate may further include a corner display area adjacent to a corner of the main display area, and the first strip portion may be arranged in the corner display area and may extend from the corner of the main display area in the first direction.

According to an embodiment, the display panel may further include a second scan line connected to another of the (1-1)th auxiliary pixel circuits and another of the (1-2)th auxiliary pixel circuits, and an emission control line connected to the one and the other of the (1-1)th auxiliary pixel circuits and the one and the other of the (1-2)th auxiliary pixel circuits.

According to an embodiment, the (1-1)th auxiliary pixel circuits and the (1-2)th auxiliary pixel circuits may be alternately arranged in the first direction.

According to an embodiment, the display panel may further include a second scan line connected to another of the (1-1)th auxiliary pixel circuits and another of the (1-2)th auxiliary pixel circuits, wherein the first scan line may be configured to transmit a first scan signal, and the second scan line may be configured to transmit a second scan signal that is later than the first scan signal by one horizontal scan period.

According to an embodiment, the display panel may further a plurality of first auxiliary display elements respectively electrically connected to the one of the (1-1)th auxiliary pixel circuits and the one of the (1-2)th auxiliary pixel circuits and emitting light of a first color, and a plurality of second auxiliary display elements respectively electrically connected to the other of the (1-1)th auxiliary pixel circuits and the other of the (1-2)th auxiliary pixel circuits and emitting light of a second color different from the first color.

According to an embodiment, the display panel may further a plurality of first auxiliary display elements respectively electrically connected to the one of the (1-1)th auxiliary pixel circuits and the other of the (1-2)th auxiliary pixel circuits and emitting light of a first color, and a plurality of second auxiliary display elements respectively electrically connected to the other of the (1-1)th auxiliary pixel circuits and the one of the (1-2)th auxiliary pixel circuits and emitting light of a second color different from the first color.

According to an embodiment, the display panel may further include a second scan line connected to another of the (1-1)th auxiliary pixel circuits and another of the (1-2)th auxiliary pixel circuits, wherein the first scan line may be configured to transmit a first scan signal, and the second scan line may be configured to transmit a second scan signal that is later than the first scan signal by two horizontal scan periods.

According to an embodiment, the display panel may further include a plurality of auxiliary display elements electrically connected to the one and the other of the (1-1)th auxiliary pixel circuits and the one and the other of the (1-2)th auxiliary pixel circuits and emitting light of a first color.

According to an embodiment, the display panel may further include a first auxiliary display element electrically connected to the one of the (1-1)th auxiliary pixel circuits and emitting light of a first color, and a second auxiliary display element electrically connected to the one of the (1-2)th auxiliary pixel circuits and emitting light of a second color different from the first color.

According to an embodiment, the display panel may further include a third data line connected to third main pixel circuits in a third column among the plurality of main pixel circuits and (1-3)th auxiliary pixel circuits that are some others of the plurality of first auxiliary pixel circuits, wherein the first scan line may be connected to one of the (1-3)th auxiliary pixel circuits.

According to one or more embodiments, a display apparatus includes a display panel including a main display area and a first strip portion extending from a corner of the main display area in a first direction and bent with a preset first curvature radius, and a cover window having a shape corresponding to a shape of the display panel and covering the display panel, wherein the display panel further includes a plurality of main pixel circuits arranged in a matrix in the main display area, a plurality of first auxiliary pixel circuits arranged in a line in the first direction in the first strip portion, a first data line connected to first main pixel circuits in a first column among the plurality of main pixel circuits and (1-1)th auxiliary pixel circuits, a second data line connected to second main pixel circuits in a second column among the plurality of main pixel circuits and (1-2)th auxiliary pixel circuits, and a first scan line connected to one of the (1-1)th auxiliary pixel circuits and one of the (1-2)th auxiliary pixel circuits, wherein the plurality of first auxiliary pixel circuits includes the (1-1)th auxiliary pixel circuits, and wherein the plurality of first auxiliary pixel circuits includes the (1-2)th auxiliary pixel circuits.

According to an embodiment, the display panel may further include a second strip portion extending from the corner of the main display area in a second direction intersecting with the first direction and bent with a preset second curvature radius, a plurality of second auxiliary pixel circuits arranged in a line in the second direction in the second strip portion, a third data line connected to third main pixel circuits in a third column among the plurality of main pixel circuits and (2-1)th auxiliary pixel circuits, a fourth data line connected to fourth main pixel circuits in a fourth column among the plurality of main pixel circuits and (2-2)th auxiliary pixel circuits, and a second scan line connected to one of the (2-1)th auxiliary pixel circuits and one of the (2-2)th auxiliary pixel circuits, wherein the plurality of second auxiliary pixel circuits includes the (2-1)th auxiliary pixel circuits, and wherein the plurality of second auxiliary pixel circuits includes the (2-2)th auxiliary pixel circuits.

According to an embodiment, the first scan line may be configured to transmit a first scan signal, and the second scan line may be configured to transmit a second scan signal substantially synchronized with the first scan signal.

According to an embodiment, the first scan line may be configured to transmit a first scan signal, and the second scan line may be configured to transmit a second scan signal that is later than the first scan signal by “n” horizontal scan periods, where “n” is a natural number.

According to an embodiment, the display panel may further include a second scan line connected to another of the (1-1)th auxiliary pixel circuits and another of the (1-2)th auxiliary pixel circuits, and an emission control line connected to the one and the other of the (1-1)th auxiliary pixel circuits and the one and the other of the (1-2)th auxiliary pixel circuits.

According to an embodiment, the (1-1)th auxiliary pixel circuits and the (1-2)th auxiliary pixel circuits may be alternately arranged in the first direction.

According to an embodiment, the display panel may further include a second scan line connected to another of the (1-1)th auxiliary pixel circuits and another of the (1-2)th auxiliary pixel circuits, the first scan line may be configured to transmit a first scan signal, and the second scan line may be configured to transmit a second scan signal that is later than the first scan signal by one horizontal scan period or two horizontal scan periods.

According to an embodiment, the display panel may further include a first auxiliary display element electrically connected to the one of the (1-1)th auxiliary pixel circuits and emitting light of a first color, and a second auxiliary display element electrically connected to the one of the (1-2)th auxiliary pixel circuits and emitting light of a second color different from the first color.

According to an embodiment, the display panel may further include a third data line connected to third main pixel circuits in a third column among the plurality of main pixel circuits and (1-3)th auxiliary pixel circuits that are some others of the plurality of first auxiliary pixel circuits, and the first scan line may be connected to one of the (1-3)th auxiliary pixel circuits.

Other aspects, features, and advantages other than those described above will become apparent from the following detailed description, the appended claims, and the accompanying drawings.

These general and particular aspects may be implemented by using systems, methods, computer programs, or any combinations of systems, methods, and computer programs.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment;

FIG. 2 is an illustrative cross-sectional view of the display apparatus taken along line I-I′ of FIG. 1;

FIG. 3 is a schematic plan view illustrating a display panel in an unfolded state, which may be included in the display apparatus of FIG. 1, according to an embodiment;

FIG. 4 is an illustrative cross-sectional view of a portion of the display panel taken along line II-II′ of FIG. 3;

FIG. 5 is an illustrative cross-sectional view of a portion of the display panel taken along line III-III′ of FIG. 3;

FIG. 6 is an arrangement diagram schematically illustrating a pixel arrangement structure applicable to a main display area of a display apparatus according to an embodiment;

FIG. 7 is an arrangement diagram schematically illustrating a pixel arrangement structure applicable to a corner display area of a display apparatus according to an embodiment;

FIG. 8 is an equivalent circuit diagram schematically illustrating a pixel circuit for driving a pixel according to an embodiment;

FIG. 9 is an equivalent circuit diagram schematically illustrating a pixel circuit for driving a pixel according to an embodiment;

FIG. 10 is an enlarged plan view of a portion of a display panel according to an embodiment;

FIG. 11 illustrates a pixel circuit arrangement structure and some signal lines of a main display area and a corner display area of a display panel according to an embodiment;

FIG. 12 is a timing diagram of control signals for operating pixel circuits illustrated in FIG. 11;

FIG. 13 is an arrangement diagram illustrating an arrangement relationship of display elements and pixel circuits arranged in a corner display area of a display panel according to an embodiment;

FIG. 14 is an arrangement diagram illustrating an arrangement relationship of display elements and pixel circuits arranged in a corner display area of a display panel according to an embodiment;

FIG. 15 is an illustrative cross-sectional view of auxiliary pixel circuits and auxiliary display elements taken along line IV-IV′ of FIG. 14;

FIG. 16 illustrates a pixel circuit arrangement structure and some signal lines of a main display area and a corner display area of a display panel according to an embodiment;

FIG. 17 is a timing diagram of control signals for operating pixel circuits illustrated in FIG. 16;

FIG. 18 illustrates a pixel circuit arrangement structure and some signal lines of a main display area and a corner display area of a display panel according to an embodiment;

FIG. 19 illustrates a pixel circuit arrangement structure and some signal lines of a main display area and a corner display area of a display panel according to an embodiment; and

FIG. 20 illustrates a pixel circuit arrangement structure and some signal lines of a main display area and a corner display area of a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

The present disclosure may include various embodiments and modifications, and certain embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below and may be embodied in various modes.

Hereinafter, embodiments will be described in detail with reference to the accompanying drawings, and in the following description, like reference numerals will denote like elements and redundant descriptions thereof will be omitted for conciseness.

It will be understood that although terms such as “first” and “second” may be used herein to describe various components, these components should not be limited by these terms and these terms are only used to distinguish one component from another component.

Also, it will be understood that the terms “comprise,” “include,” and “have” used herein specify the presence of stated features or components, but do not preclude the presence or addition of one or more other features or components.

It will be understood that when a layer, region, or component is referred to as being “on” another layer, region, or component, it may be “directly on” the other layer, region, or component or may be “indirectly on” the other layer, region, or component with one or more intervening layers, regions, or components therebetween.

Sizes of elements in the drawings may be exaggerated for convenience of description. In other words, because the sizes and thicknesses of elements in the drawings are arbitrarily illustrated for convenience of description, the disclosure is not limited thereto.

When a certain embodiment may be implemented differently, a particular process order may be performed differently from the described order. For example, two consecutively described processes may be performed substantially at the same time or may be performed in an order opposite to the described order.

As used herein, the word “or” means logical “or” so, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

It will be understood that when a layer, region, or component is referred to as being “connected to” another layer, region, or component, it may be “directly connected to” the other layer, region, or component or may be “indirectly connected to” the other layer, region, or component with one or more intervening layers, regions, or components therebetween. For example, it will be understood that when a layer, region, or component is referred to as being “electrically connected to” another layer, region, or component, it may be “directly electrically connected to” the other layer, region, or component or may be “indirectly electrically connected to” the other layer, region, or component with one or more intervening layers, regions, or components therebetween.

The x axis, the y axis, and the z axis are not limited to three axes of the rectangular coordinate system and may be interpreted in a broader sense. For example, the x axis, the y axis, and the z axis may be perpendicular to one another or may represent different directions that are not perpendicular to one another.

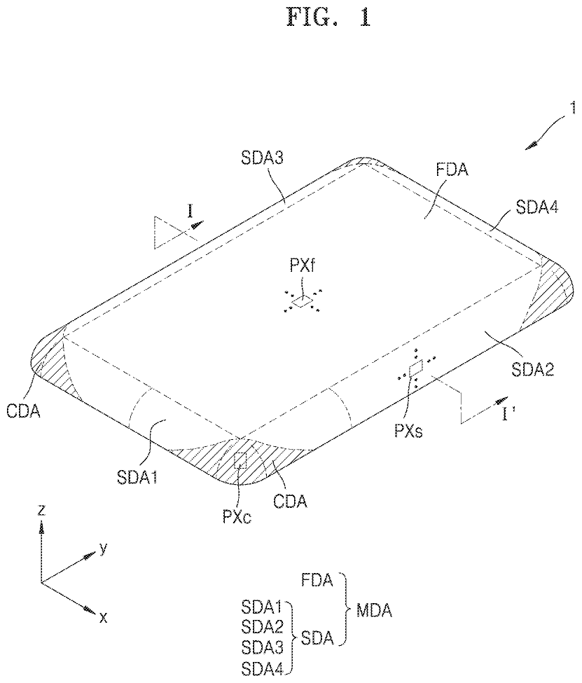

FIG. 1 is a perspective view schematically illustrating a display apparatus according to an embodiment.

Referring to FIG. 1, a display apparatus 1 may be an apparatus displaying a moving image or a still image and may correspond to various apparatuses providing display screens of televisions, notebook computers, monitors, billboards, and Internet of Things (IoT) as well as portable electronic apparatuses such as mobile phones, smart phones, tablet personal computers (PCs), smart watches, watch phones, mobile communication terminals, electronic notebooks, electronic books, portable multimedia players (PMPs), navigation, and ultra mobile PCs (UMPCs).

The display apparatus 1 may include a main display area MDA including a front display area FDA and a side display area SDA, and a corner display area CDA.

The front display area FDA may be an area arranged at a front portion of the display apparatus 1 and may be an area formed flat without being bent. The front display area FDA may have a rectangular shape including a short side in the x direction and a long side in the y direction. However, the disclosure is not limited thereto. The front display area FDA may have various polygonal shapes other than a rectangular shape and may have a polygonal shape in which a corner where a short side and a long side meet each other is rounded.

The side display area SDA may include a first side display area SDA1, a second side display area SDA2, a third side display area SDA3, and a fourth side display area SDA4.

The first side display area SDA1 may be an area extending from a first side of the front display area FDA and bent with a certain curvature. The first side display area SDA1 may extend from a lower side of the front display area FDA. The first side display area SDA1 may be an area arranged at a lower surface of the display apparatus 1.

The second side display area SDA2 may be an area extending from a second side of the front display area FDA and bent with a certain curvature. The second side display area SDA2 may extend from a right side of the front display area FDA. The second side display area SDA2 may be an area arranged at a right surface of the display apparatus 1.

The third side display area SDA3 may be an area extending from a third side of the front display area FDA and bent with a certain curvature. The third side display area SDA3 may extend from a left side of the front display area FDA. The third side display area SDA3 may be an area arranged at a left surface of the display apparatus 1.

The fourth side display area SDA4 may be an area extending from a fourth side of the front display area FDA and bent with a certain curvature. The fourth side display area SDA4 may extend from an upper side of the front display area FDA. The fourth side display area SDA4 may be an area arranged at an upper surface of the display apparatus 1.

The corner display area CDA may be an area extending from a corner of the main display area MDA and bent with a certain curvature. The corner display area CDA may be arranged between the first to fourth side display areas SDA1 to SDA4. For example, the corner display area CDA may be arranged between the first side display area SDA1 and the second side display area SDA2, between the first side display area SDA1 and the third side display area SDA3, between the second side display area SDA2 and the fourth side display area SDA4, and between the third side display area SDA3 and the fourth side display area SDA4.

The display apparatus 1 may provide an image by using front pixels PXf arranged in the front display area FDA, side pixels PXs arranged in the side display area SDA, and corner pixels (or auxiliary pixels) PXc arranged in the corner display area CDA.

In some embodiments, an image displayed in the corner display area CDA or the side display area SDA may be an auxiliary image and may have a lower resolution than an image displayed in the front display area FDA. That is, the number of corner pixels PXc arranged per unit area in the corner display area CDA may be less than the number of front pixels PXf arranged per unit area in the front display area FDA. In some embodiments, the resolution of the side display area SDA may be equal to or lower than the resolution of the front display area FDA.

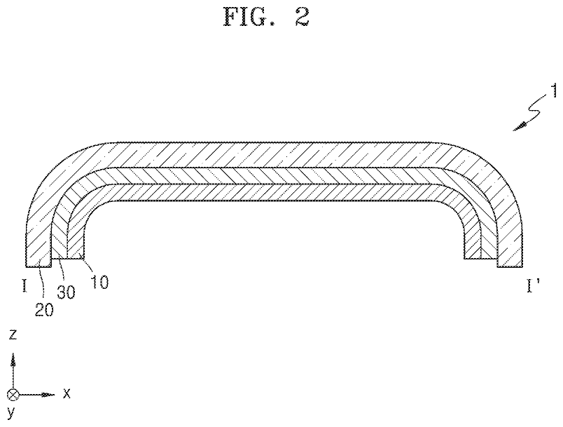

FIG. 2 is an illustrative cross-sectional view of the display apparatus taken along line I-I′ of FIG. 1.

Referring to FIG. 2, the display apparatus 1 may include a display panel 10 and a cover window 20 disposed on the display panel 10.

The cover window 20 may cover and protect the display panel 10. The cover window 20 may include a transparent material. The cover window 20 may include, for example, glass or plastic. When the cover window 20 includes plastic, the cover window 20 may be flexible.

The shape of the cover window 20 may correspond to the shape of the display apparatus 1. For example, as illustrated in FIG. 1, when the display apparatus 1 includes the side display area SDA and the corner display area CDA, the cover window 20 may include a side portion corresponding to the side display area SDA and a corner portion corresponding to the corner display area CDA. The side portion and the corner portion of the cover window 20 may include a curved surface and in this case, may have a constant curvature or a variable curvature.

The display panel 10 may be disposed under the cover window 20. The cover window 20 and the display panel 10 may be coupled through an adhesive member 30. The adhesive member 30 may include an optically clear adhesive (OCA) film or an optically clear resin (OCR).

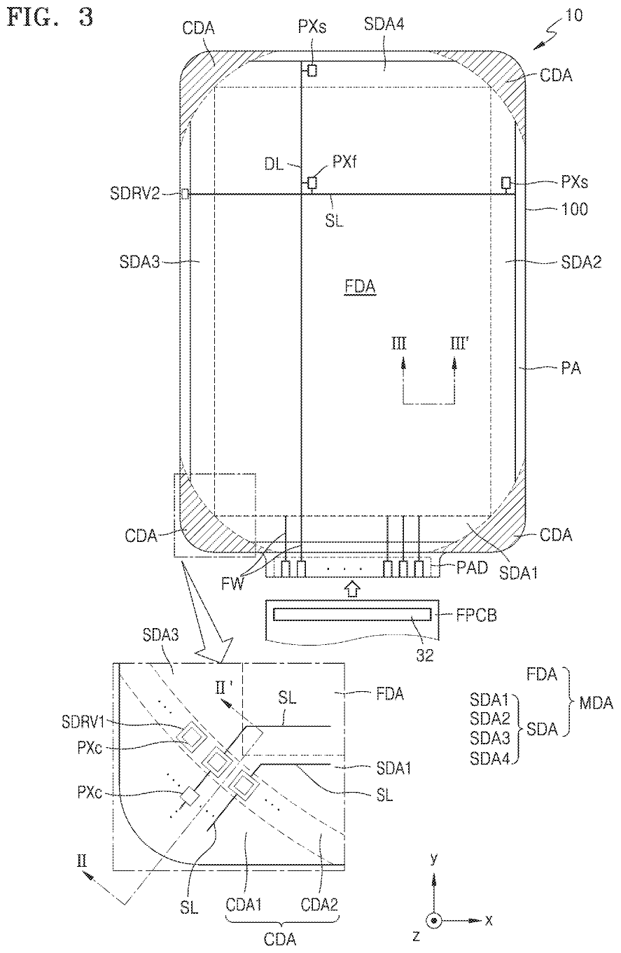

FIG. 3 is a schematic plan view illustrating a display panel in an unfolded state, which may be included in the display apparatus of FIG. 1, according to an embodiment.

Referring to FIG. 3, various components constituting the display panel 10 may be disposed on a substrate 100. The substrate 100 may include a front display area FDA, a side display area SDA, a corner display area CDA, and a peripheral area PA.

A plurality of front pixels PXf may be arranged in the front display area FDA, and a main image may be displayed by the front pixels PXf. Each front pixel PXf may emit red, green, or blue light.

The side display area SDA may be arranged on the upper, lower, left, and right sides of the front display area FDA. A plurality of side pixels PXs may be arranged in the side display area SDA, and a side image may be displayed by the side pixels PXs. The side image may form an entire image together with the main image, and the side image may be an image independent from the main image.

The corner display area CDA may be arranged in an area extending from a corner of the main display area MDA. The corner display area CDA may be arranged between two side display areas SDA. A plurality of corner pixels PXc are arranged in the corner display area CDA, and a corner image may be displayed by the corner pixels PXc. The corner image may form an entire image together with the main image and the side image, and the corner image may be an image independent from the main image.

The corner display area CDA may include a first corner display area CDA1 and a second corner display area CDA2. The first corner display area CDA1 may be arranged closer to an edge of the substrate 100 than the second corner display area CDA2, and the second corner display area CDA2 may be arranged between the first corner display area CDA1 and the front display area FDA.

In addition to the corner pixel PXc, a first scan driving circuit SDRV1 may be arranged in the second corner display area CDA2. The first scan driving circuit SDRV1 may provide a scan signal for driving the corner pixels PXc arranged in the corner display area CDA. Also, the first scan driving circuit SDRV1 may provide a scan signal for driving the front pixels PXf or the side pixels PXs arranged in the front display area FDA or the side display area SDA. In some embodiments, the first scan driving circuit SDRV1 may be simultaneously connected to a pixel circuit driving the corner pixel PXc and a pixel circuit driving the front pixel PXf to provide the same scan signal thereto. In this case, a scan line SL connected to the first scan driving circuit SDRV1 may extend from both sides of the first scan driving circuit SDRV1 to the front display area FDA and the corner display area CDA.

The peripheral area PA may be arranged outside the side display area SDA. A second scan driving circuit SDRV2 and a terminal unit PAD may be arranged in the peripheral area PA.

The second scan driving circuit SDRV2 may provide a scan signal for driving the front pixels PXf and the side pixels PXs. The second scan driving circuit SDRV2 may be arranged on the right side of the second side display area SDA2 or on the left side of the third side display area SDA3 and may be connected to the scan line SL extending in the x direction.

The terminal unit PAD may be arranged under the first side display area SDA1. The terminal unit PAD may be exposed by not being covered by an insulating layer, to be connected to a display circuit board FPCB. A display driver 32 may be arranged at the display circuit board FPCB.

The display driver 32 may generate a control signal to be transmitted to the first scan driving circuit SDRV1 and the second scan driving circuit SDRV2. Also, the display driver 32 may generate a data signal. The generated data signal may be transmitted to the pixels PXf, PXs, and PXc through a fanout line FW and a data line DL connected to the fanout line FW. The data lines DL may extend in the y direction to be respectively connected to the pixel circuits driving the front pixels PXf. The data lines DL may extend in the y direction to be respectively connected to the pixel circuits driving the side pixels PXs. The data lines DL may extend from the corner of the main display area MDA (see FIG. 1) to be connected to the pixel circuits driving the corner pixels PXc. In some embodiments, some data lines DL may be simultaneously connected to the pixel circuits driving the front pixels PXf and the pixel circuits driving the corner pixels PXc. In other embodiments, some data lines DL may be simultaneously connected to the pixel circuits driving the side pixels PXs and the pixel circuits driving the corner pixels PXc.

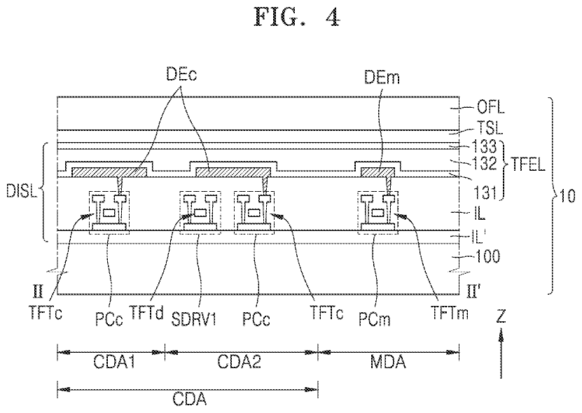

FIG. 4 is an illustrative cross-sectional view of a portion of the display panel taken along line II-II′ of FIG. 3.

Referring to FIG. 4, the display panel 10 may include a corner display area CDA and a main display area MDA, and the corner display area CDA may include a first corner display area CDA1 and a second corner display area CDA2. The display panel 10 may include a substrate 100, a display layer DISL on the substrate 100, a touch screen layer TSL, and an optical functional layer OFL.

The display layer DISL may include a circuit layer including thin film transistors TFTm, TFTc, and TFTd, a display element layer including display elements DEm and DEc, and a thin film encapsulation layer TFEL. Insulating layers IL and IL′ may be arranged in the display layer DISL and between the substrate 100 and the display layer DISL.

The substrate 100 may include an insulating material such as glass, quartz, or polymer resin. The substrate 100 may include a rigid substrate or a flexible substrate capable of bending, folding, rolling, or the like.

A main pixel circuit PCm and a main display element DEm connected thereto may be arranged in the main display area MDA of the display panel 10. The main pixel circuit PCm may include at least one thin film transistor TFTm and may control the light emission of the main display element DEm. Moreover, because the main display area MDA includes the front display area FDA and the side display area SDA as described above with reference to FIG. 1, the main pixel circuit PCm may correspond to a front pixel circuit or a side pixel circuit and the main display element DEm may correspond to a front display element or a side display element.

A corner pixel circuit PCc and a corner display element DEc connected thereto may be arranged in the first corner display area CDA1 and the second corner display area CDA2 of the display panel 10. The corner pixel circuit PCc may include at least one thin film transistor TFTc and may control the light emission of the corner display element DEc.

Moreover, as described above with reference to FIG. 3, the first scan driving circuit SDRV1 may be arranged in the second corner display area CDA2. The first scan driving circuit SDRV1 may include at least one thin film transistor TFTd and may provide a scan signal to the corner pixel circuits PCc arranged in the corner display area CDA. The corner display elements DEc arranged in the first corner display area CDA1 and the second corner display area CDA2 may be arranged in the same pixel arrangement. Due to the uniform pixel arrangement of the corner display elements DEc, the corner display element DEc may overlap the first scan driving circuit SDRV1 in the second corner display area CDA2.

The corner display area CDA may be an auxiliary display area, and the resolution of the corner display area CDA may be less than the resolution of the main display area MDA. That is, the number per unit area of corner display elements DEc arranged in the corner display area CDA may be less than the number per unit area of main display elements DEm arranged in the main display area MDA.

The corner display element DEc arranged in the corner display area CDA may be larger than the main display element DEm arranged in the main display area MDA. For example, an emission area of the corner display element DEc may be larger than an emission area of the main display element DEm arranged in the main display area MDA. This may be to provide the same or similar luminance as the main display area MDA even with a low resolution of the corner display area CDA.

The main display element DEm and the corner display element DEc that are display elements may be covered with the thin film encapsulation layer TFEL. In some embodiments, the thin film encapsulation layer TFEL may include at least one inorganic encapsulation layer and at least one organic encapsulation layer as illustrated in FIG. 4. In an embodiment, the thin film encapsulation layer TFEL may include first and second inorganic encapsulation layers 131 and 133 and an organic encapsulation layer 132 therebetween.

The first inorganic encapsulation layer 131 and the second inorganic encapsulation layer 133 may include one or more inorganic insulating materials such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂) and may be formed by chemical vapor deposition (CVD) or the like. The organic encapsulation layer 132 may include a polymer-based material. The polymer-based material may include silicon-based resin, acryl-based resin, epoxy-based resin, polyimide, polyethylene, or the like.

The touch screen layer TSL may be configured to obtain coordinate information according to an external input, for example, a touch event. The touch screen layer TSL may include a touch electrode and touch lines connected to the touch electrode. The touch screen layer TSL may sense an external input by using a self capacitance method or a mutual capacitance method.

The touch screen layer TSL may be formed on the thin film encapsulation layer TFEL. Alternatively, the touch screen layer TSL may be separately formed on a touch substrate and then coupled onto the thin film encapsulation layer TFEL through an adhesive layer such as an optically clear adhesive (OCA). In an embodiment, the touch screen layer TSL may be directly formed on the thin film encapsulation layer TFEL, and in this case, an adhesive layer may not be between the touch screen layer TSL and the thin film encapsulation layer TFEL.

The optical functional layer OFL may include an anti-reflection layer. The anti-reflection layer may be configured to reduce the reflectance of light (external light) incident from the outside toward the display apparatus 1 (see FIG. 1). In some embodiments, the optical functional layer OFL may include a polarization film. In some embodiments, the optical functional layer OFL may include a filter plate including a black matrix and color filters.

The display panel 10 may include a light emitting display panel including a light emitting element. For example, the display panel 10 may include an organic light emitting display panel using an organic light emitting diode (OLED) as a light emitting element, a micro light emitting diode (LED) display panel using a micro LED as a light emitting element, a quantum dot organic light emitting display panel using quantum dots and an OLED, or an inorganic light emitting display panel using an inorganic semiconductor as a light emitting element. Hereinafter, a case where the display panel 10 includes an organic light emitting display panel will be mainly described.

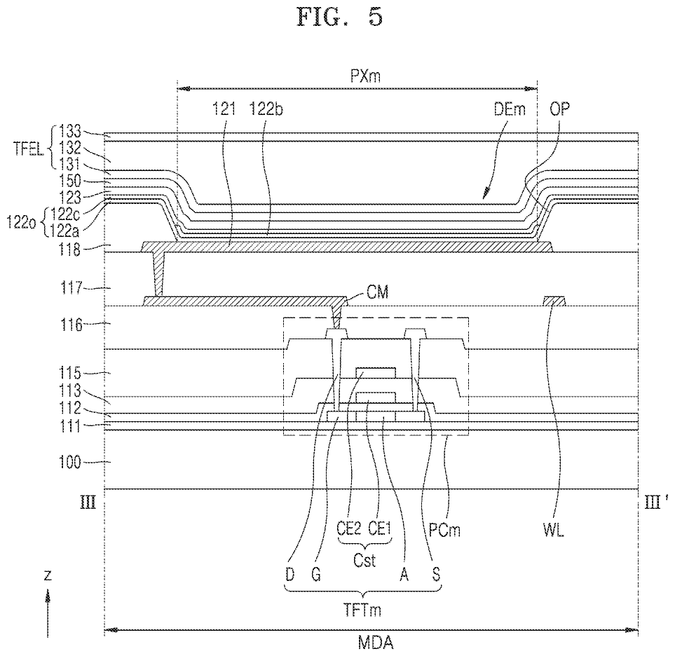

FIG. 5 is an illustrative cross-sectional view of a portion of the display panel taken along line III-III′ of FIG. 3.

Referring to FIG. 5, a main pixel circuit PCm including at least one thin film transistor TFT and a storage capacitor Cst and a main display element DEm connected to the main pixel circuit PCm may be arranged in the main display area MDA. A main pixel PXm may be implemented as an emission area of the main display element DEm. Moreover, because the main display area MDA includes the front display area FDA and the side display area SDA as described above with reference to FIG. 1, the main pixel PXm may correspond to the front pixel PXf or the side pixel PXs.

Hereinafter, a structure in which the components included in the display panel 10 are stacked will be described.

The substrate 100 may include an insulating material such as glass, quartz, or polymer resin. The substrate 100 may include a rigid substrate or a flexible substrate capable of bending, folding, rolling, or the like. In some embodiments, the substrate 100 may include a stack structure of organic layer/inorganic layer/organic layer.

A buffer layer 111 may be located on the substrate 100 to reduce or block the penetration of foreign materials, moisture, or external air from under the substrate 100 and may provide a flat surface on the substrate 100. The buffer layer 111 may include an inorganic material such as oxide or nitride, an organic material, or an organic/inorganic composite and may include a single-layer or multiple-layer structure of an inorganic material and an organic material. A barrier layer (not illustrated) for blocking the penetration of external air may be further included between the substrate 100 and the buffer layer 111. In some embodiments, the buffer layer 111 may include silicon oxide (SiO₂) or silicon nitride (SiNₓ).

A thin film transistor TFTm may be disposed over the buffer layer 111. The thin film transistor TFTm may include a semiconductor layer A, a gate electrode G, a source electrode S, and a drain electrode D. The thin film transistor TFTm may be connected to the main display element DEm to drive the main display element DEm.

The semiconductor layer A may be disposed on the buffer layer 111 and may include polysilicon. In other embodiments, the semiconductor layer A may include amorphous silicon. In other embodiments, the semiconductor layer A may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The semiconductor layer A may include a channel area and a source area and a drain area that are doped with dopants.

A first gate insulating layer 112 may be arranged to cover the semiconductor layer A. The first gate insulating layer 112 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The first gate insulating layer 112 may include a single layer or multiple layers including the above inorganic insulating material.

The gate electrode G may be disposed over the first gate insulating layer 112 to overlap the semiconductor layer A. The gate electrode G may include molybdenum (Mo), aluminum (Al), copper (Cu), titanium (Ti), or the like and may include a single layer or multiple layers. For example, the gate electrode G may include a single layer of Mo.

A second gate insulating layer 113 may be arranged to cover the gate electrode G. The second gate insulating layer 113 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The second gate insulating layer 113 may include a single layer or multiple layers including the above inorganic insulating material.

An upper electrode CE2 of the storage capacitor Cst may be disposed over the second gate insulating layer 113. The upper electrode CE2 of the storage capacitor Cst may overlap the gate electrode G thereunder. The gate electrode G and the upper electrode CE2 overlapping each other with the second gate insulating layer 113 therebetween may constitute the storage capacitor Cst. The gate electrode G may function as a lower electrode CE1 of the storage capacitor Cst.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu) and may include a single layer or multiple layers of the above material.

An interlayer insulating layer 115 may be formed to cover the upper electrode CE2. The interlayer insulating layer 115 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The interlayer insulating layer 115 may include a single layer or multiple layers including the above inorganic insulating material.

The source electrode S and the drain electrode D may be disposed on the interlayer insulating layer 115. The source electrode S and the drain electrode D may include a conductive material including molybdenum (Mo), aluminum (Al), copper (Cu), titanium (Ti), or the like and may include a single layer or multiple layers including the above material. For example, the source electrode S and the drain electrode D may include a multilayer structure of Ti/Al/Ti.

A first organic insulating layer 116 may be disposed on the source electrode S and the drain electrode D. The first organic insulating layer 116 may include a general-purpose polymer such as photosensitive polyimide, polyimide, polystyrene (PS), polycarbonate (PC), benzocyclobutene (BCB), hexamethyldisiloxane (HMDSO), or polymethylmethacrylate (PMMA), a polymer derivative having a phenolic group, an acrylic polymer, an imide-based polymer, an aryl ether-based polymer, an amide-based polymer, a fluorine-based polymer, a p-xylene-based polymer, or a vinyl alcohol-based polymer.

Alternatively, the first organic insulating layer 116 may include a siloxane-based organic material. The siloxane-based organic material may include hexamethyldisiloxane, octamethyltrisiloxane, decamethyltetrasiloxane, dodecamethylpentasiloxane, and polydimethylsiloxane.

A connection electrode CM and various lines WL, for example, a driving voltage line or a data line, may be disposed over the first organic insulating layer 116, which may be advantageous for high integration.

A second organic insulating layer 117 may be disposed on the first organic insulating layer 116 to cover the connection electrode CM and the line WL. The second organic insulating layer 117 may have a flat upper surface such that a pixel electrode 121 disposed thereover may be formed flat. The second organic insulating layer 117 may include a siloxane-based organic material having high light transmittance and high flatness. The siloxane-based organic material may include hexamethyldisiloxane, octamethyltrisiloxane, decamethyltetrasiloxane, dodecamethylpentasiloxane, and polydimethylsiloxane.

Alternatively, the second organic insulating layer 117 may include a general-purpose polymer such as photosensitive polyimide, polyimide, benzocyclobutene (BCB), hexamethyldisiloxane (HMDSO), polymethylmethacrylate (PMMA), or polystyrene (PS), a polymer derivative having a phenolic group, an acrylic polymer, an imide-based polymer, an aryl ether-based polymer, an amide-based polymer, a fluorine-based polymer, a p-xylene-based polymer, or a vinyl alcohol-based polymer.

The main display element DEm may be disposed on the second organic insulating layer 117. The pixel electrode 121 of the main display element DEm may be connected to the main pixel circuit PCm through the connection electrode CM disposed on the first organic insulating layer 116.

The pixel electrode 121 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 121 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. For example, the pixel electrode 121 may have a structure including layers formed of ITO, IZO, ZnO, or In₂O₃ over/under the reflective layer. In this case, the pixel electrode 121 may have a stack structure of ITO/Ag/ITO.

A pixel definition layer 118 may cover an edge of the pixel electrode 121 on the second organic insulating layer 117 and may include an opening OP exposing a central portion of the pixel electrode 121. The size and shape of the emission area of the main display element DEm, that is, the main pixel PXm, may be defined by the opening OP.

The pixel definition layer 118 may prevent the occurrence of an arc or the like at the edge of the pixel electrode 121 by increasing the distance between the edge of the pixel electrode 121 and an opposite electrode 123 over the pixel electrode 121. The pixel definition layer 118 may be formed of an organic insulating material such as polyimide, polyamide, acrylic resin, benzocyclobutene, hexamethyldisiloxane (HMDSO), or phenol resin by spin coating or the like.

An emission layer 122b formed to correspond to the pixel electrode 121 may be arranged in the opening OP of the pixel definition layer 118. The emission layer 122b may include a high molecular weight material or a low molecular weight material and may emit red, green, blue, or white light.

An organic functional layer 122o may be disposed over or under the emission layer 122b. The organic functional layer 122o may include a first functional layer 122a or a second functional layer 122c. At least one of the first functional layer 122a and the second functional layer 122c may be omitted.

The first functional layer 122a may be disposed under the emission layer 122b. The first functional layer 122a may include a single layer or multiple layers including an organic material. The first functional layer 122a may include a hole transport layer (HTL) having a single-layer structure. Alternatively, the first functional layer 122a may include a hole injection layer (HIL) and an HTL. The first functional layer 122a may be integrally formed to correspond to the main display elements DEm included in the main display area MDA.

The second functional layer 122c may be disposed over the emission layer 122b. The second functional layer 122c may include a single layer or multiple layers including an organic material. The second functional layer 122c may include an electron transport layer (ETL) or an electron injection layer (EIL). The second functional layer 122c may be integrally formed to correspond to the main display elements DEm included in the main display area MDA.

The opposite electrode 123 may be disposed over the second functional layer 122c. The opposite electrode 123 may include a conductive material having a low work function. For example, the opposite electrode 123 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 123 may further include a layer such as ITO, IZO, ZnO, or In₂O₃ on the (semi)transparent layer including the above material. The opposite electrode 123 may be integrally formed to correspond to the main display elements DEm included in the main display area MDA.

The layers from the pixel electrode 121 to the opposite electrode 123 formed in the main display area MDA may constitute an organic light emitting diode OLED.

An upper layer 150 including an organic material may be formed on the opposite electrode 123. The upper layer 150 may be arranged to protect the opposite electrode 123 and improve light extraction efficiency. The upper layer 150 may include an organic material having a higher refractive index than the opposite electrode 123. Alternatively, the upper layer 150 may include a stack of layers having different refractive indexes. For example, the upper layer 150 may include a stack of a high refractive index layer/a low refractive index layer/a high refractive index layer. In this case, the refractive index of the high refractive index layer may be about 1.7 or more, and the refractive index of the low refractive index layer may be about 1.3 or less.

The upper layer 150 may further include LiF. Alternatively, the upper layer 150 may further include an inorganic insulating material such as silicon oxide (SiO₂) or silicon nitride (SiNₓ).

A thin film encapsulation layer TFEL may be disposed on the upper layer 150. The thin film encapsulation layer TFEL may prevent external moisture or foreign substances from penetrating into the organic light emitting diode OLED.

The thin film encapsulation layer TFEL may include at least one inorganic encapsulation layer and at least one organic encapsulation layer, and in this regard, FIG. 5 illustrates a structure in which a first inorganic encapsulation layer 131, an organic encapsulation layer 132, and a second inorganic encapsulation layer 133 are stacked. In other embodiments, the number of organic encapsulation layers, the number of inorganic encapsulation layers, and the stacking order thereof may be modified.

The first inorganic encapsulation layer 131 and the second inorganic encapsulation layer 133 may include one or more inorganic insulating materials such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂) and may be formed by chemical vapor deposition (CVD) or the like. The organic encapsulation layer 132 may include a polymer-based material. The polymer-based material may include silicon-based resin, acryl-based resin, epoxy-based resin, polyimide, polyethylene, or the like. The first inorganic encapsulation layer 131, the organic encapsulation layer 132, and the second inorganic encapsulation layer 133 may be integrally formed to cover the main display area MDA.

Moreover, although a stack structure of the main display area MDA has been described as an example in FIG. 5, the stack structure may also be similarly applied to the corner display area CDA.

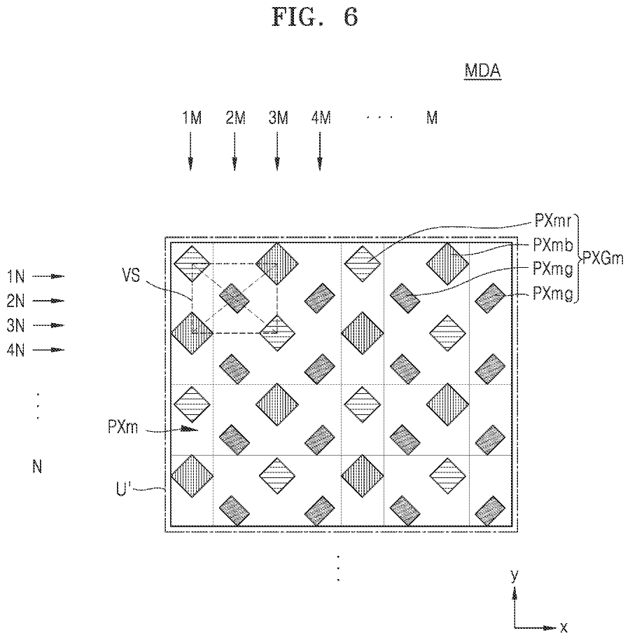

FIG. 6 is an arrangement diagram schematically illustrating a pixel arrangement structure applicable to a main display area of a display apparatus according to an embodiment.

Referring to FIG. 6, a plurality of main pixels PXm may be arranged in the main display area MDA. Herein, the pixel may refer to an emission area as a minimum unit for implementing an image. A main pixel group PXGm may include a set of certain main pixels PXm. The main pixel group PXGm may include a first main pixel PXmr, a second main pixel PXmg, and a third main pixel PXmb that emit different colors. The first main pixel PXmr, the second main pixel PXmg, and the third main pixel PXmb may respectively implement red, green, and blue colors. In an embodiment, one main pixel group PXGm may include one first main pixel PXmr, two second main pixels PXmg, and one third main pixel PXmb.

As illustrated in FIG. 6, the main pixels PXm arranged in the main display area MDA may be arranged in a PENTILE® structure.

A plurality of first main pixels PXmr and a plurality of third main pixels PXmb may be alternately arranged in a first row 1N, a plurality of second main pixels PXmg may be arranged at certain intervals in a second row 2N adjacent thereto, a plurality of third main pixels PXmb and a plurality of first main pixels PXmr may be alternately arranged in a third row 3N adjacent thereto, a plurality of second main pixels PXmg may be arranged at certain intervals in a fourth row 4N adjacent thereto, and this pixel arrangement may be repeated up to an Nth row. In this case, the third main pixel PXmb and the first main pixel PXmr may be larger than the second main pixel PXmg.

The plurality of first main pixels PXmr and third main pixels PXmb arranged in the first row 1N and the plurality of second main pixels PXmg arranged in the second row 2N may be alternately arranged. Thus, a plurality of first main pixels PXmr and a plurality of third main pixels PXmb may be alternately arranged in a first column 1M, a plurality of second main pixels PXmg may be arranged at certain intervals in a second column 2M adjacent thereto, a plurality of third main pixels PXmb and a plurality of first main pixels PXmr may be alternately arranged in a third column 3M adjacent thereto, a plurality of second main pixels PXmg may be arranged at certain intervals in a fourth column 4M adjacent thereto, and this pixel arrangement may be repeated up to an Mth column.

When this pixel arrangement structure is expressed differently, it may be said that the first main pixels PXmr are arranged at the first and third vertexes facing each other among the vertexes of a virtual square VS having a central point of the second main pixel PXmg as a central point thereof and the third main pixels PXmb are arranged at the second and fourth vertexes that are the other vertexes thereof. In this case, the virtual square VS may be variously modified into a rectangle, a rhombus, a square, or the like.

Such a pixel arrangement structure may be referred to as a PENTILE® matrix structure or a PENTILE® structure, and high resolution may be implemented by a small number of pixels by applying a rendering drive that represents colors by sharing adjacent pixels.

Although FIG. 6 illustrates that a plurality of main pixels PXm are arranged in a PENTILE® matrix structure, the disclosure is not limited thereto. For example, a plurality of main pixels PXm may be arranged in various forms such as a stripe structure, a mosaic arrangement structure, and a delta arrangement structure.

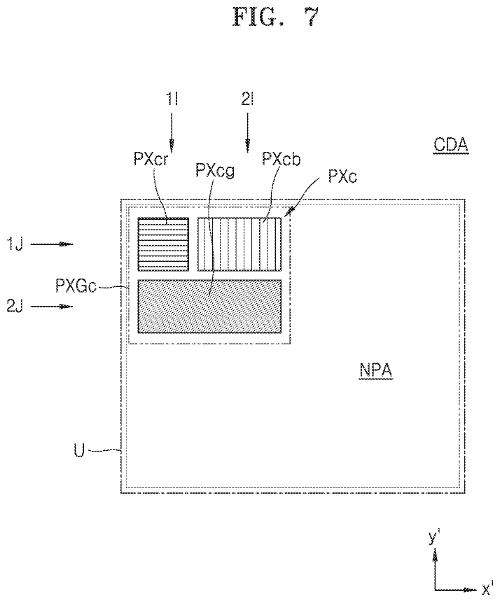

FIG. 7 is an arrangement diagram schematically illustrating a pixel arrangement structure applicable to a corner display area of a display apparatus according to an embodiment.

Referring to FIG. 7, a plurality of corner pixels PXc may be arranged in the corner display area CDA. A corner pixel group PXGc may include a set of certain corner pixels PXc. The corner pixel PXc may include a first corner pixel PXcr, a second corner pixel PXcg, and a third corner pixel PXcb that emit different colors. The first corner pixel PXcr, the second corner pixel PXcg, and the third corner pixel PXcb may respectively implement red, green, and blue colors. In the present embodiment, one corner pixel PXc may include a total of three corner pixels PXc including a first corner pixel PXcr, a second corner pixel PXcg, and a third corner pixel PXcb.

In the present embodiment, the first corner pixel PXcr and the third corner pixel PXcb may be alternately arranged in a first row 1J, and the second corner pixel PXcg may be arranged in a second row 2J adjacent thereto.

In this case, the second corner pixel PXcg may be arranged across a first column 1I and a second column 2I. That is, the second corner pixel PXcg may have a rectangular shape having a long side in the x′ direction.

The length of the second corner pixel PXcg in the x′ direction may be equal to or greater than the sum of the length of the first corner pixel PXcr in the x′ direction and the length of the third corner pixel PXcb in the x′ direction. Accordingly, the size of the second corner pixel PXcg may be greater than the size of the first corner pixel PXcr and the third corner pixel PXcb. This arrangement structure will be referred to as an S-stripe structure.

Although FIG. 7 illustrates that a plurality of corner pixels PXc are arranged in an S-stripe structure, the disclosure is not limited thereto. For example, a plurality of corner pixels PXc may be arranged in various forms such as a stripe structure, a mosaic arrangement structure, a delta arrangement structure, and a PENTILE® matrix structure.

In the corner display area CDA, a basis unit U including a bundle of a certain number of corner pixel groups PXGc and a non-pixel area NPA in which no pixel is arranged may be repeatedly arranged in the x′ direction and the y′ direction. In FIG. 7, the basic unit U may have a form in which on pixel group PXGc and a non-pixel area NPA arranged therearound are bundled in a square shape. The basic unit U may be a division of the repeated form and may not mean a disconnection of the configuration.

A corresponding unit U′ having the same area as the basic unit U may be set in the main display area MDA. In this case, the number of main pixels PXm included in the corresponding unit U′ may be greater than the number of corner pixels PXc included in the basic unit U. That is, the number of corner pixels PXc included in the basic unit U may be 3, and the number of main pixels PXm included in the corresponding unit U′ may be 32.

In the present embodiment, an area occupied by one corner pixel group PXGc in the basic unit U may be about ¼ of the area of the basic unit U. FIG. 7 illustrates that the basic unit U includes only one corner pixel group PXGc; however, in other embodiments, the basic unit U may include two or more corner pixel groups PXGc. The number or arrangement of corner pixels PXc included in the corner pixel group PXGc may be designed and modified according to the resolution of the corner display area CDA. Also, the area of corner pixels PXc included in the corner pixel group PXGc may be variously modified.

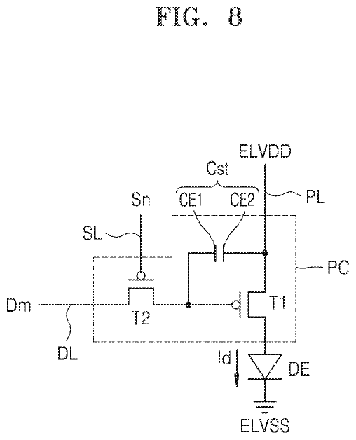

FIG. 8 is an equivalent circuit diagram schematically illustrating a pixel circuit for driving a pixel according to an embodiment.

Referring to FIG. 8, a pixel circuit PC may be connected to a display element DE to implement light emission of pixels. The pixel circuit PC may be connected to a scan line SL and a data line DL. The display element DE may include an organic light emitting diode OLED. The cathode of the display element DE may be a common electrode to which a second driving voltage ELVSS is applied.

The pixel circuit PC may include a first transistor T1, a second transistor T2, and a storage capacitor Cst.

The first transistor T1 may be a driving transistor whose drain current is determined according to a gate-source voltage, and the second transistor may be a switching transistor that is turned on/off according to a gate-source voltage, substantially a gate voltage. The first transistor T1 and the second transistor T2 may be formed as a thin film transistor.

The first transistor T1 may be referred to as a driving transistor, and the second transistor T2 may be referred to as a scan transistor.

The storage capacitor Cst may be connected between a driving voltage line PL and the gate of the driving transistor T1. The storage capacitor Cst may include an upper electrode CE2 connected to the driving voltage line PL and a lower electrode CE1 connected to the gate of the driving transistor T1. The storage capacitor Cst may be configured to store a voltage corresponding to the difference between a voltage received from the scan transistor T2 and a first driving voltage ELVDD supplied to the driving voltage line PL.

The driving transistor T1 may be configured to control the level of a driving current Id flowing from the driving voltage line PL to the display element DE according to the gate-source voltage. The display element DE may emit light with a certain brightness according to the driving current Id. The driving transistor T1 may include a gate connected to the lower electrode CE1 of the storage capacitor Cst, a source connected to the driving voltage line PL, and a drain connected to the display element DE.

The scan transistor T2 may be configured to transmit a data voltage Dm to the gate of the driving transistor T1 in response to a scan signal Sn. The scan transistor T2 may include a gate connected to the scan line SL, a source connected to the data line DL, and a drain connected to the gate of the driving transistor T1.

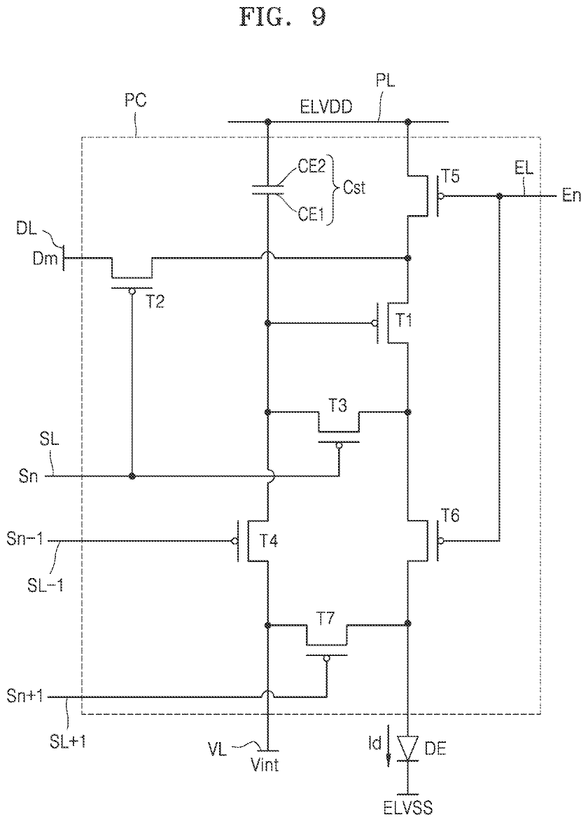

Although FIG. 8 illustrates an example in which the pixel circuit PC includes two transistors and one storage capacitor, the disclosure is not limited thereto. For example, the pixel circuit PC may include three or more transistors, or two or more storage capacitors. In an embodiment, the pixel circuit PC may include seven transistors and one storage capacitor as illustrated in FIG. 9 described below.

FIG. 9 is an equivalent circuit diagram schematically illustrating a pixel circuit for driving a pixel according to an embodiment.

Referring to FIG. 9, a pixel circuit PC may be connected to a display element DE to implement light emission of pixels. The display element DE may include an organic light emitting diode OLED.

For example, as illustrated in FIG. 9, the pixel circuit PC may include first to seventh transistors T1 to T7 and a storage capacitor Cst. The first to seventh transistors T1 to T7 and the storage capacitor Cst may be connected to first to third scan lines SL, SL−1, and SL+1 configured to respectively transmit first to third scan signals Sn, Sn−1, and Sn+1, a data line DL configured to transmit a data voltage Dm, an emission control line EL configured to transmit an emission control signal En, a driving voltage line PL configured to transmit a first driving voltage ELVDD, an initialization voltage line VL configured to transmit an initialization voltage Vint, and a common electrode to which a second driving voltage ELVSS is applied.

The first transistor T1 may be a driving transistor whose drain current is determined according to a gate-source voltage, and the second to seventh transistors T2 to T7 may be switching transistors that are turned on/off according to a gate-source voltage, substantially a gate voltage. The first to seventh transistors T1 to T7 may be thin film transistors.

The first transistor T1 may be referred to as a driving transistor, the second transistor T2 may be referred to as a scan transistor, the third transistor T3 may be referred to as a compensation transistor, the fourth transistor T4 may be referred to as a gate initialization transistor, the fifth transistor T5 may be referred to as a first emission control transistor, the sixth transistor T6 may be referred to as a second emission control transistor, and the seventh transistor T7 may be referred to as an anode initialization transistor.

The storage capacitor Cst may be connected between the driving voltage line PL and the gate of the driving transistor T1. The storage capacitor Cst may include an upper electrode CE2 connected to the driving voltage line PL and a lower electrode CE1 connected to the gate of the driving transistor T1.

The driving transistor T1 may be configured to control the level of a driving current Id flowing from the driving voltage line PL to the display element DE according to the gate-source voltage. The driving transistor T1 may include a gate connected to the lower electrode CE1 of the storage capacitor Cst, a source connected to the driving voltage line PL through the first emission control transistor T5, and a drain connected to the display element DE through the second emission control transistor T6.

The driving transistor T1 may be configured to output the driving current Id to the display element DE according to the gate-source voltage. The level of the driving current Id may be determined based on the difference between the gate-source voltage and the threshold voltage of the driving transistor T1. The display element DE may receive the driving current Id from the driving transistor T1 and emit light with a brightness according to the level of the driving current Id.

The scan transistor T2 may be configured to transmit the data voltage Dm to the source of the driving transistor T1 in response to the first scan signal Sn. The scan transistor T2 may include a gate connected to the first scan line SL, a source connected to the data line DL, and a drain connected to the source of the driving transistor T1.

The compensation transistor T3 may be connected in series between the drain and the gate of the driving transistor T1 and may be configured to connect the drain and the gate of the driving transistor T1 to each other in response to the first scan signal Sn. The compensation transistor T3 may include a gate connected to the first scan line SL, a source connected to the drain of the driving transistor T1, and a drain connected to the gate of the driving transistor T1. FIG. 9 illustrates that the compensation transistor T3 includes one transistor; however, in another embodiment, the compensation transistor T3 may include two transistors connected in series to each other.

The gate initialization transistor T4 may be configured to apply the initialization voltage Vint to the gate of the driving transistor T1 in response to the second scan signal Sn−1. The gate initialization transistor T4 may include a gate connected to the second scan line SL−1, a source connected to the gate of the driving transistor T1, and a drain connected to the initialization voltage line VL. FIG. 9 illustrated that the gate initialization transistor T4 includes one transistor; however, in another embodiment, the gate initialization transistor T4 may include two transistors connected in series to each other.

The anode initialization transistor T7 may be configured to apply the initialization voltage Vint to the anode of the display element DE in response to the third scan signal Sn+1. The anode initialization transistor T7 may include a gate connected to the third scan line SL+1, a source connected to the anode of the display element DE, and a drain connected to the initialization voltage line VL.

The first emission control transistor T5 may be configured to connect the driving voltage line PL and the source of the driving transistor T1 to each other in response to the emission control signal En. The first emission control transistor T5 may include a gate connected to the emission control line EL, a source connected to the driving voltage line PL, and a drain connected to the source of the driving transistor T1.

The second emission control transistor T6 may be configured to connect the drain of the driving transistor T1 and the anode of the display element DE to each other in response to the emission control signal En. The second emission control transistor T6 may include a gate connected to the emission control line EL, a source connected to the drain of the driving transistor T1, and a drain connected to the anode of the display element DE.

The second scan signal Sn−1 may be substantially synchronized with the first scan signal Sn of the previous row. The third scan signal Sn+1 may be substantially synchronized with the first scan signal Sn. According to another example, the third scan signal Sn+1 may be substantially synchronized with the first scan signal Sn of the next row.

In the present embodiment, the first to seventh transistors T1 to T7 may include a semiconductor layer including silicon. For example, the first to seventh transistors T1 to T7 may include a semiconductor layer including low-temperature polysilicon (LTPS). The polysilicon material may have high electron mobility (over 100 cm²/Vs or more) and thus may have low energy consumption and high reliability.

As another example, the semiconductor layers of the first to seventh transistors T1 to T7 may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the semiconductor layer may be an InSnZnO (ITZO) semiconductor layer, an InGaZnO (IGZO) semiconductor layer, or the like.

As another example, some semiconductor layers of the first to seventh transistors T1 to T7 may include low-temperature polysilicon (LTPS), and other semiconductor layers may include an oxide semiconductor (IGZO or the like).

Hereinafter, a particular operation process of a pixel of a display apparatus according to an embodiment will be described in detail. As illustrated in FIG. 9, it is assumed that the first to seventh transistors T1 to T7 are p-type MOSFETs.

First, when a high-level emission control signal En is received, the first emission control transistor T5 and the second emission control transistor T6 may be turned off, the driving transistor T1 may stop the output of the driving current Id, and the display element DE may stop light emission.

Thereafter, during a gate initialization period in which a low-level second scan signal Sn−1 is received, the gate initialization transistor T4 may be turned on and the initialization voltage Vint may be applied to the gate of the driving transistor T1, that is, the lower electrode CE1 of the storage capacitor Cst. The difference (ELVDD−Vint) between the first driving voltage ELVDD and the initialization voltage Vint may be stored in the storage capacitor Cst.

Thereafter, during a data write period in which a low-level first scan signal Sn is received, the scan transistor T2 and the compensation transistor T3 may be turned on and the data voltage Dm may be received at the source of the driving transistor T1. The driving transistor T1 may be diode-connected by the compensation transistor T3 and may be forward biased. The gate voltage of the driving transistor T1 may rise from the initialization voltage Vint. When the gate voltage of the driving transistor T1 becomes equal to a data compensation voltage (Dm−|Vth|) that is equal to a decrease by a threshold voltage Vth of the driving transistor T1 from the data voltage Dm, the driving transistor T1 may be turned off and the rise of the gate voltage of the driving transistor T1 may stop. Accordingly, the difference (ELVDD−Dm+|Vth|) between the first driving voltage ELVDD and the data compensation voltage (Dm−|Vth|) may be stored in the storage capacitor Cst.

Also, during an anode initialization period in which a low-level third scan signal Sn+1 is received, the anode initialization transistor T7 may be turned on and the initialization voltage Vint may be applied to the anode of the display element DE. By applying the initialization voltage Vint to the anode of the display element DE to completely stop the display element DE from emitting light, a phenomenon in which the display element DE slightly emits light even when the pixel receives the data voltage Dm corresponding to a black gray scale in the next frame may be eliminated.

The first scan signal Sn and the third scan signal Sn+1 may be substantially synchronized with each other, and in this case, the data write period and the anode initialization period may be the same period.

Thereafter, when a low-level emission control signal En is received, the first emission control transistor T5 and the second emission control transistor T6 may be turned on, the driving transistor T1 may output the driving current Id corresponding to the voltage stored in the storage capacitor Cst, that is, the voltage (ELVDD−Dm) obtained by subtracting the threshold voltage |Vth| of the driving transistor T1 from the source-gate voltage (ELVDD−Dm+|Vth|) of the driving transistor T1, and the display element DE may emit light with a luminance corresponding to the level of the driving current Id.

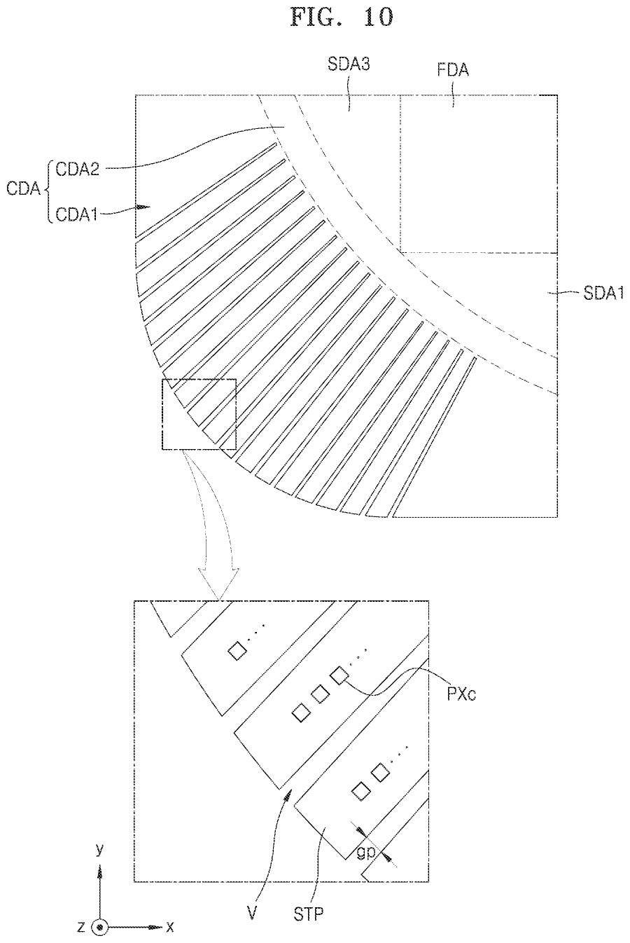

FIG. 10 is an enlarged plan view of a portion of a display panel according to an embodiment. Particularly, FIG. 10 is an enlarged view of the corner display area CDA of the display panel 10 and illustrates a state where the display panel 10 is unfolded.

Referring to FIG. 10, the display panel 10 may include a plurality of strip portions STP and a plurality of cutout portions V arranged to correspond to the corner display area CDA. The plurality of cutout portions V may be located between the plurality of strip portions STP and may be areas formed by cutting out the substrate 100. The plurality of cutout portions V may be through portions provided through the display panel 10.

One end of each of the plurality of strip portions STP may be arranged apart from each other with a certain gap gp therebetween. Empty spaces may be formed between the plurality of strip portions STP by the gap gp, and the empty spaces may respectively correspond to the plurality of cutout portions V. The gap gp between the plurality of strip portions STP may vary. For example, as illustrated in FIG. 10, the gap gp between the plurality of strip portions STP may increase away from the front display area FDA toward the corner display area CDA. As another example, the gap gp between the plurality of strip portions STP may be constant instead of variable. That is, the plurality of strips portions STP may be arranged radially or may be arranged in parallel to each other.

The plurality of strip portions STP may be connected at a portion adjacent to the front display area FDA. The plurality of strip portions STP may extend from the front display area FDA. The extended lengths of the plurality of strip portions STP may be different from each other. The extended lengths of the plurality of strip portions STP may be different from each other depending on the distances of the plurality of strip portions STP from a central portion of the corner display area CDA. For example, the strip portions STP located at a central portion among the plurality of strip portions STP may have greater lengths extending toward the corner display area CDA than the other strip portions STP. The extended length of each of the plurality of strip portions STP may decrease as each of the plurality of strip portions STP is arranged farther from the central portion of the corner display area CDA.

Each cutout portion V may pass through the front surface and the bottom surface of the display panel 10. Each cutout portion V may improve the flexibility of the display panel 10. Also, because the shape of the cutout portions V changes when an external force (e.g., bending, curving, or pulling) is applied to the display panel 10, a stress generated when the display panel 10 is deformed may be easily reduced and thus the durability of the display panel 10 may be improved.

When an external force is applied to the display panel 10, the area or shape of the cutout portion V may be changed and the position of the strip portion STP may also be changed. For example, when a force is applied to bend the edges of the display panel 10 and the corner side therebetween, as the gap gp between the plurality of strip portions STP decreases, the area of the cutout portion V may also decrease and the adjacent strip portions STP may contact each other.

As such, when an external force is applied to the display panel 10, there may be a change in the gap gp between the plurality of strip portions STP and the area of the cutout portion V and there may be no change in the shape of the plurality of strip portions STP. That is, a pixel circuit and a display element may be disposed on the plurality of strip portions STP, and the pixel circuit and the display element disposed on the plurality of strip portions STP may be protected because the shape of the plurality of strip portions STP does not change even when an external force is applied to the display panel 10.

Because the shape of the plurality of strip portions STP may not change, the corner pixels PXc may be arranged in the corner display area CDA of the display panel 10 having a curvature. Accordingly, a display area in which an image is implemented may be extended from the front display area FDA and the side display area SDA to the corner display area CDA. The corner pixels PXc disposed on the strip portion STP may be arranged apart from each other in one direction.

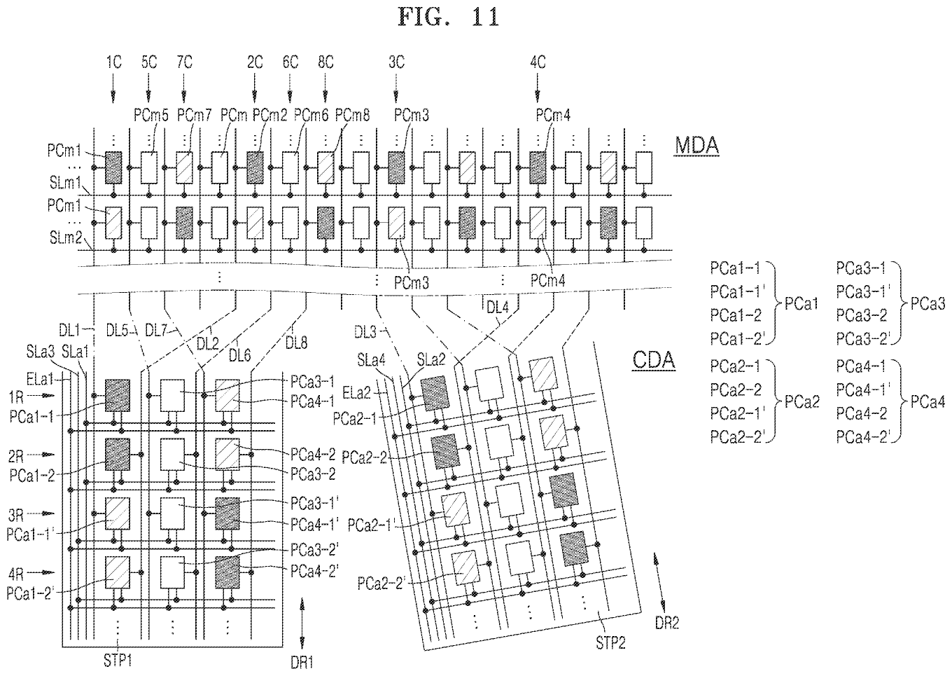

FIG. 11 illustrates a pixel circuit arrangement structure and some signal lines of a main display area and a corner display area of a display panel according to an embodiment.

Referring to FIG. 11, a plurality of main pixel circuits PCm may be arranged in a matrix in the main display area MDA. As described above with reference to FIG. 4, each of the main pixel circuits PCm may be electrically connected to the main display elements DEm to control the light emission of the main display elements DEm.

Among the plurality of main pixel circuits PCm, the main pixel circuits PCm arranged in the same column may be connected to the same data line. For example, among the plurality of main pixel circuits PCm, first main pixel circuits PCm1 in a first column 1C may be connected to a first data line DL1, second main pixel circuits PCm2 in a second column 2C may be connected to a second data line DL2, third main pixel circuits PCm3 in a third column 3C may be connected to a third data line DL3, fourth main pixel circuits PCm4 in a fourth column 4C may be connected to a fourth data line DL4, fifth main pixel circuits PCm5 in a fifth column 5C may be connected to a fifth data line DL5, sixth main pixel circuits PCm6 in a sixth column 6C may be connected to a sixth data line DL6, seventh main pixel circuits PCm7 in a seventh column 7C may be connected to a seventh data line DL7, and eighth main pixel circuits PCm8 in an eighth column 8C may be connected to an eighth data line DL8.

Among the plurality of main pixel circuits PCm, the main pixel circuits PCm arranged in the same row may be connected to the same scan line. For example, among the plurality of main pixel circuits PCm, main pixel circuits PCm arranged in some rows may be connected to a first main scan line SLm1, and main pixel circuits PCm arranged in some other rows may be connected to a second main scan line SLm2.

A first strip portion STP1 and a second strip portion STP2 may be arranged in the corner display area CDA. The first strip portion STP1 may extend from the corner of the main display area MDA in a first direction DR1, and the second strip portion STP2 may extend from the corner of the main display area MDA in a second direction DR2.

A plurality of first auxiliary pixel circuits (or corner pixel circuits) PCa1 may be arranged in a line in the first direction DR1 in the first strip portion STP1. As described above with reference to FIG. 4, the first auxiliary pixel circuits PCa1 may be respectively electrically connected to the corner display elements (or auxiliary display elements) DEc to control the light emission of the corner display elements DEc.

(1-1)th auxiliary pixel circuits PCa1-1 and PCa1-1′, which are some of the plurality of first auxiliary pixel circuits PCa1, and (1-2)th auxiliary pixel circuits PCa1-2 and PCa1-2′, which are some others thereof, may be respectively connected to different data lines. For example, the (1-1)th auxiliary pixel circuits PCa1-1 and PCa1-1′ that are some of the plurality of first auxiliary pixel circuits PCa1 may be connected to the first data line DL1, and the (1-2)th auxiliary pixel circuits PCa1-2 and PCa1-2′ that are some others of the plurality of first auxiliary pixel circuits PCa1 may be connected to the second data line DL2.

In an embodiment, as illustrated in FIG. 11, the (1-1)th auxiliary pixel circuits PCa1-1 and PCa1-1′ and the (1-2)th auxiliary pixel circuits PCa1-2 and PCa1-2′ may be alternately arranged in the first direction DR1.

The (1-1)th auxiliary pixel circuits PCa1-1 and PCa1-1′ and the (1-2)th auxiliary pixel circuits PCa1-2 and PCa1-2′ may share scan lines with each other. For example, one (PCa1-1) of the (1-1)th auxiliary pixel circuits PCa1-1 and PCa1-1′ and one (PCa1-2) of the (1-2)th auxiliary pixel circuits PCa1-2 and PCa1-2′ may be connected to a first auxiliary scan line SLa1. Another (PCa1-1′) of the (1-1)th auxiliary pixel circuits PCa1-1 and PCa1-1′ and another (PCa1-2′) of the (1-2)th auxiliary pixel circuits PCa1-2 and PCa1-2′ may be connected to a third auxiliary scan line SLa3.

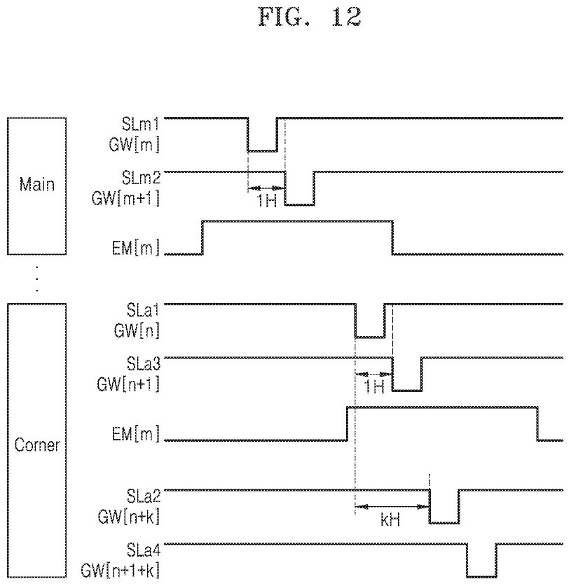

In an embodiment, as illustrated in FIG. 12 described below, the first auxiliary scan line SLa1 may be configured to transmit a first auxiliary scan signal GW[n], and the third auxiliary scan line SLa3 may be configured to transmit a third auxiliary scan signal GW[n+1] that is later than the first auxiliary scan signal GW[n] by one horizontal scan period 1H.

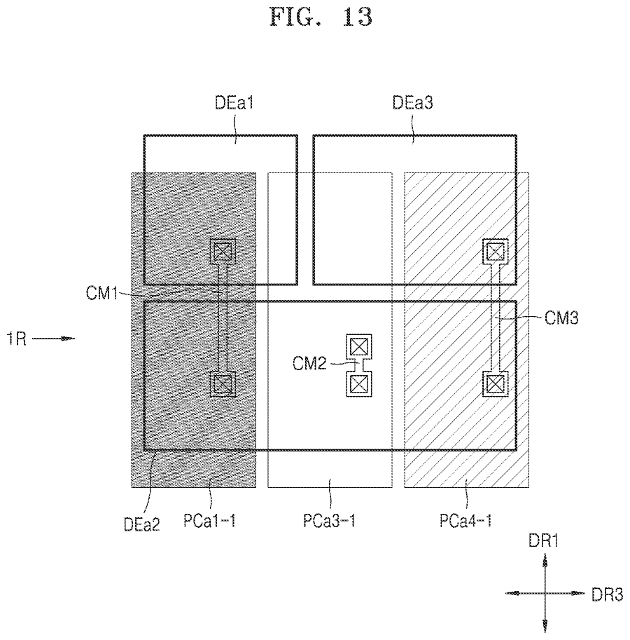

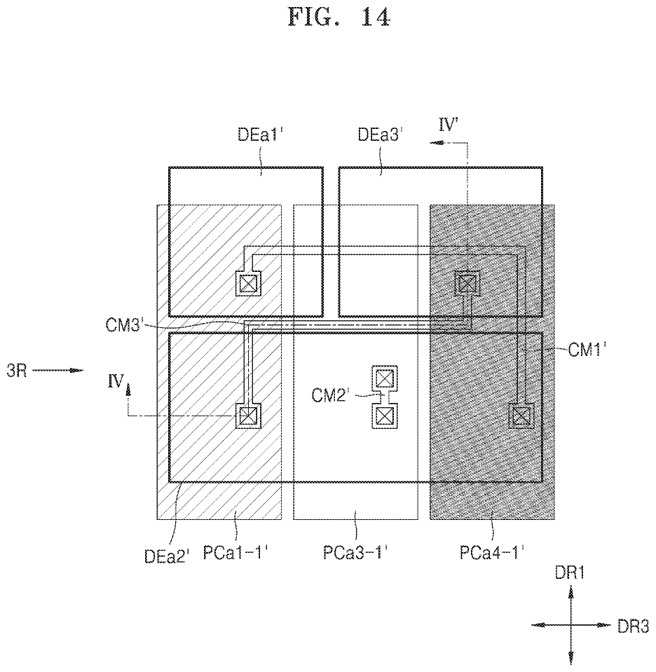

In this case, the (1-1)th auxiliary pixel circuits PCa1-1 and PCa1-1′ sharing the first data line DL1 with the first main pixel circuits PCm1 of the first column 1C arranged in a PENTILE® matrix structure may be respectively electrically connected to the auxiliary display elements emitting light of different colors. The (1-2)th auxiliary pixel circuits PCa1-2 and PCa1-2′ sharing the second data line DL2 with the second main pixel circuits PCm2 of the second column 2C arranged in a PENTILE® matrix structure may be respectively electrically connected to the auxiliary display elements emitting light of different colors. For example, one (PCa1-1) of the (1-1)th auxiliary pixel circuits PCa1-1 and PCa1-1′ and one (PCa1-2) of the (1-2)th auxiliary pixel circuits PCa1-2 and PCa1-2′ may be respectively electrically connected to the auxiliary display elements emitting light of a first color (e.g., red), and another (PCa1-1′) of the (1-1)th auxiliary pixel circuits PCa1-1 and PCa1-1′ and another (PCa1-2′) of the (1-2)th auxiliary pixel circuits PCa1-2 and PCa1-2′ may be respectively electrically connected to the auxiliary display elements emitting light of a second color (e.g., blue). This will be described in more detail with reference to FIGS. 13 and 14.

The (1-1)th auxiliary pixel circuits PCa1-1 and PCa1-1′ and the (1-2)th auxiliary pixel circuits PCa1-2 and PCa1-2′ may share emission control lines with each other. For example, one (PCa1-1) and another (PCa1-1′) of the (1-1)th auxiliary pixel circuits PCa1-1 and PCa1-1′ and one (PCa1-2) and another (PCa1-2′) of the (1-2)th auxiliary pixel circuits PCa1-2 and PCa1-2′ may be connected to a first auxiliary emission control line ELa1.

FIG. 11 illustrates that four first auxiliary pixel circuits PCa1 are connected to the first auxiliary emission control line ELa1; however, in other embodiments, the number of auxiliary pixel circuits PCa1 connected to the first auxiliary emission control line ELa1 may vary. For example, two first auxiliary pixel circuits PCa1 may be connected to the first auxiliary emission control line ELa1.

As a comparative example, auxiliary pixel circuits arranged in a line in the lengthwise direction of the strip portion may be connected to the same data line. In this case, the auxiliary pixel circuits may be respectively connected to different scan lines in order to apply different data voltages to the auxiliary pixel circuits. Signal lines (e.g., data lines, scan lines, and emission control lines) for driving the auxiliary pixel circuits may be shared from the main display area to both sides of the strip portion. In this case, when the auxiliary pixel circuit is used as the pixel circuit of FIG. 9, the total number of shared signal lines may be 3M+(3/2)N+1. Here, M may be the number of columns of auxiliary pixel circuits arranged in a matrix in the strip portion, and N may be the number of rows of auxiliary pixel circuits arranged in a matrix in the strip portion.

Moreover, as in an embodiment, auxiliary pixel circuits arranged in a line in the lengthwise direction of the strip portion may be respectively connected to different data lines, and the auxiliary pixel circuits connected to different data lines may share scan lines with each other. In this case, the number of data lines shared from the main display area MDA to the strip portion may increase, but the number of scan lines thereof may decrease. For example, when the auxiliary pixel circuit is used as the pixel circuit of FIG. 9, the total number of shared signal lines may be 6M+((3/2)N)/2+1. For example, when M is 3 and N is 16, the total number may be 34 according to the equation of a comparative example and may be 31 according to the equation of an embodiment. Thus, the total number of signal lines shared from the main display area MDA to the strip portion may decrease. Because the total number of signal lines shared to the strip portion decreases, the number of pixels arranged in the strip portion may be increased and the resolution of the corner display area CDA may be increased.

A plurality of second auxiliary pixel circuits PCa2 may be arranged in a line in the second direction DR2 in the second strip portion STP2.

(2-1)th auxiliary pixel circuits PCa2-1 and PCa2-1′, which are some of the plurality of second auxiliary pixel circuits PCa2, and (2-2)th auxiliary pixel circuits PCa2-2 and PCa2-2′, which are some others thereof, may be respectively connected to different data lines. For example, the (2-1)th auxiliary pixel circuits PCa2-1 and PCa2-1′ that are some of the plurality of second auxiliary pixel circuits PCa2 may be connected to the third data line DL3, and the (2-2)th auxiliary pixel circuits PCa2-2 and PCa2-2′ that are some others of the plurality of second auxiliary pixel circuits PCa2 may be connected to the fourth data line DL4.

In an embodiment, as illustrated in FIG. 11, the (2-1)th auxiliary pixel circuits PCa2-1 and PCa2-1′ and the (2-2)th auxiliary pixel circuits PCa2-2 and PCa2-2′ may be alternately arranged in the second direction DR2.

The (2-1)th auxiliary pixel circuits PCa2-1 and PCa2-1′ and the (2-2)th auxiliary pixel circuits PCa2-2 and PCa2-2′ may share scan lines with each other. For example, one (PCa2-1) of the (2-1)th auxiliary pixel circuits PCa2-1 and PCa2-1′ and one (PCa2-2) of the (2-2)th auxiliary pixel circuits PCa2-2 and PCa2-2′ may be connected to a second auxiliary scan line SLa2. Another (PCa2-1′) of the (2-1)th auxiliary pixel circuits PCa2-1 and PCa2-1′ and another (PCa2-2′) of the (2-2)th auxiliary pixel circuits PCa2-2 and PCa2-2′ may be connected to a fourth auxiliary scan line SLa4.

In an embodiment, as illustrated in FIG. 12 described below, the first auxiliary scan line SLa1 may be configured to transmit the first auxiliary scan signal GW[n], and the second auxiliary scan line SLa2 may be configured to transmit a second auxiliary scan signal GW[n+k] that is later than the first auxiliary scan signal GW[n] by “k” horizontal scan periods kH. The fourth auxiliary scan line SLa4 may be configured to transmit a fourth auxiliary scan signal GW[n+1+k] that is later than the second auxiliary scan signal GW[n+k] by one horizontal scan period 1H. Here, “k” may be an integer greater than or equal to 0. When “k” is 0, the first auxiliary scan signal GW[n] and the second auxiliary scan signal GW[n+k] may be substantially synchronized.

The (2-1)th auxiliary pixel circuits PCa2-1 and PCa2-1′ and the (2-2)th auxiliary pixel circuits PCa2-2 and PCa2-2′ may share emission control lines with each other. For example, one (PCa2-1) and another (PCa2-1′) of the (2-1)th auxiliary pixel circuits PCa2-1 and PCa2-1′ and one (PCa2-2) and another (PCa2-2′) of the (2-2)th auxiliary pixel circuits PCa2-2 and PCa2-2′ may be connected to a second auxiliary emission control line ELa2.

A plurality of third auxiliary pixel circuits PCa3 may be arranged in a line in the first direction DR1 in the first strip portion STP1.

(3-1)th auxiliary pixel circuits PCa3-1 and PCa3-1′, which are some of the plurality of third auxiliary pixel circuits PCa3, and (3-2)th auxiliary pixel circuits PCa3-2 and PCa3-2′, which are some others thereof, may be respectively connected to different data lines. For example, the (3-1)th auxiliary pixel circuits PCa3-1 and PCa3-1′ that are some of the plurality of third auxiliary pixel circuits PCa3 may be connected to the fifth data line DL5, and the (3-2)th auxiliary pixel circuits PCa3-2 and PCa3-2′ that are some others of the plurality of third auxiliary pixel circuits PCa3 may be connected to the sixth data line DL6.

In an embodiment, as illustrated in FIG. 11, the (3-1)th auxiliary pixel circuits PCa3-1 and PCa3-1′ and the (3-2)th auxiliary pixel circuits PCa3-2 and PCa3-2′ may be alternately arranged in the first direction DR1.

The (3-1)th auxiliary pixel circuits PCa3-1 and PCa3-1′ and the (3-2)th auxiliary pixel circuits PCa3-2 and PCa3-2′ may share scan lines with each other. For example, one (PCa3-1) of the (3-1)th auxiliary pixel circuits PCa3-1 and PCa3-1′ and one (PCa3-2) of the (3-2)th auxiliary pixel circuits PCa3-2 and PCa3-2′ may be connected to the first auxiliary scan line SLa1. Another (PCa3-1′) of the (3-1)th auxiliary pixel circuits PCa3-1 and PCa3-1′ and another (PCa3-2′) of the (3-2)th auxiliary pixel circuits PCa3-2 and PCa3-2′ may be connected to the third auxiliary scan line SLa3.

The (3-1)th auxiliary pixel circuits PCa3-1 and PCa3-1′ and the (3-2)th auxiliary pixel circuits PCa3-2 and PCa3-2′ may share emission control lines with each other. For example, one (PCa3-1) and another (PCa3-1′) of the (3-1)th auxiliary pixel circuits PCa3-1 and PCa3-1′ and one (PCa3-2) and another (PCa3-2′) of the (3-2)th auxiliary pixel circuits PCa3-2 and PCa3-2′ may be connected to the first auxiliary emission control line ELa1.

A plurality of fourth auxiliary pixel circuits PCa4 may be arranged in a line in the first direction DR1 in the first strip portion STP1.

(4-1)th auxiliary pixel circuits PCa4-1 and PCa4-1′, which are some of the plurality of fourth auxiliary pixel circuits PCa4, and (4-2)th auxiliary pixel circuits PCa4-2 and PCa4-2′, which are some others thereof, may be respectively connected to different data lines. For example, the (4-1)th auxiliary pixel circuits PCa4-1 and PCa4-1′ that are some of the plurality of fourth auxiliary pixel circuits PCa4 may be connected to the seventh data line DL7, and the (4-2)th auxiliary pixel circuits PCa4-2 and PCa4-2′ that are some others of the plurality of fourth auxiliary pixel circuits PCa4 may be connected to the eighth data line DL8.

In an embodiment, as illustrated in FIG. 11, the (4-1)th auxiliary pixel circuits PCa4-1 and PCa4-1′ and the (4-2)th auxiliary pixel circuits PCa4-2 and PCa4-2′ may be alternately arranged in the first direction DR1.

The (4-1)th auxiliary pixel circuits PCa4-1 and PCa4-1′ and the (4-2)th auxiliary pixel circuits PCa4-2 and PCa4-2′ may share scan lines with each other. For example, one (PCa4-1) of the (4-1)th auxiliary pixel circuits PCa4-1 and PCa4-1′ and one (PCa4-2) of the (4-2)th auxiliary pixel circuits PCa4-2 and PCa4-2′ may be connected to the first auxiliary scan line SLa1. Another (PCa4-1′) of the (4-1)th auxiliary pixel circuits PCa4-1 and PCa4-1′ and another (PCa4-2′) of the (4-2)th auxiliary pixel circuits PCa4-2 and PCa4-2′ may be connected to the third auxiliary scan line SLa3.

The (4-1)th auxiliary pixel circuits PCa4-1 and PCa4-1′ and the (4-2)th auxiliary pixel circuits PCa4-2 and PCa4-2′ may share emission control lines with each other. For example, one (PCa4-1) and another (PCa4-1′) of the (4-1)th auxiliary pixel circuits PCa4-1 and PCa4-1′ and one (PCa4-2) and another (PCa4-2′) of the (4-2)th auxiliary pixel circuits PCa4-2 and PCa4-2′ may be connected to the first auxiliary emission control line ELa1.

FIG. 12 is a timing diagram of control signals for operating pixel circuits illustrated in FIG. 11.

Referring to FIG. 12, in a non-emission period in which a main emission control signal EM[m] has a high level, a first main scan signal GW[m] may have a low-level pulse voltage and a second main scan signal (GW[m+1]) may have a low-level pulse voltage. Each of a period in which the first main scan signal GW[m] has a low-level pulse voltage and a period in which the second main scan signal GW[m+1] has a low-level pulse voltage may be referred to as a data write period.

The difference between the timing at which the first main scan signal GW[m] has a falling edge and the timing at which the second main scan signal GW[m+1] has a falling edge may be one horizontal scan period 1H.

In a non-emission period in which an auxiliary emission control signal EM[n] has a high level, a first auxiliary scan signal GW[n] may have a low-level pulse voltage and a third auxiliary scan signal (GW[n+1]) may have a low-level pulse voltage. Each of a period in which the first auxiliary scan signal GW[n] has a low-level pulse voltage and a period in which the third auxiliary scan signal GW[n+1] has a low-level pulse voltage may be referred to as a data write period.

The difference between the timing at which the first auxiliary scan signal GW[n] has a falling edge and the timing at which the third auxiliary scan signal GW[n+1] has a falling edge may be one horizontal scan period 1H.

Even when the auxiliary pixel circuits arranged in the corner display area CDA (see FIG. 11) and the main pixel circuits arranged in the main display area MDA (see FIG. 11) share a data line, because data is written at different timings, sequential driving may be performed.

In an embodiment, the first auxiliary scan line SLa1 arranged in the first strip portion STP1 (see FIG. 11) may be configured to transmit the first auxiliary scan signal GW[n], and the second auxiliary scan line SLa2 arranged in the second strip portion STP2 (see FIG. 11) may be configured to transmit the second auxiliary scan signal GW[n+k] that is later than the first auxiliary scan signal GW[n] by “k” horizontal scan periods kH. The fourth auxiliary scan line SLa4 arranged in the second strip portion STP2 may be configured to transmit the fourth auxiliary scan signal GW[n+1+k] that is later than the second auxiliary scan signal GW[n+k] by one horizontal scan period 1H. Here, “k” may be an integer greater than or equal to 0. When “k” is 0, the first auxiliary scan signal GW[n] and the second auxiliary scan signal GW[n+k] may be substantially synchronized.

FIG. 13 is an arrangement diagram illustrating an arrangement relationship of display elements and pixel circuits arranged in a corner display area of a display panel according to an embodiment. Particularly, FIG. 13 illustrates the arrangement relationship of auxiliary display elements and auxiliary pixel circuits in a first row 1R of FIG. 11.

First, referring to FIG. 13, a (1-1)th auxiliary pixel circuit PCa1-1, a (3-1)th auxiliary pixel circuit PCa3-1, and a (4-1)th auxiliary pixel circuit PCa1-1 in the first row 1R may be sequentially arranged in a third direction DR3.

A first auxiliary display element DEa1 may emit light of a first color (e.g., red) and may be electrically connected to the (1-1)th auxiliary pixel circuit PCa1-1. The first auxiliary display element DEa1 may be connected to the (1-1)th auxiliary pixel circuit PCa1-1 by a first connection electrode CM1. The first auxiliary display element DEa1 may overlap the (1-1)th auxiliary pixel circuit PCa1-1. The first auxiliary display element DEa1 may implement the first corner pixel PXcr illustrated in FIG. 7 described above.

A second auxiliary display element DEa2 may emit light of a second color (e.g., green) and may be electrically connected to the (3-1)th auxiliary pixel circuit PCa3-1. The second auxiliary display element DEa2 may be connected to the (3-1)th auxiliary pixel circuit PCa3-1 by a second connection electrode CM2. The second auxiliary display element DEa2 may overlap the (1-1)th auxiliary pixel circuit PCa1-1, the (3-1)th auxiliary pixel circuit PCa3-1, and the (4-1)th auxiliary pixel circuit PCa4-1. The second auxiliary display element DEa2 may implement the second corner pixel PXcg illustrated in FIG. 7 described above.

A third auxiliary display element DEa3 may emit light of a third color (e.g., blue) and may be electrically connected to the (4-1)th auxiliary pixel circuit PCa4-1. The third auxiliary display element DEa3 may be connected to the (4-1)th auxiliary pixel circuit PCa4-1 by a third connection electrode CM3. The third auxiliary display element DEa3 may overlap the (4-1)th auxiliary pixel circuit PCa4-1. The third auxiliary display element DEa3 may implement the third corner pixel PXcb illustrated in FIG. 7 described above.

Although the description has been made based on the (1-1)th auxiliary pixel circuit PCa1-1, the (3-1)th auxiliary pixel circuit PCa3-1, and the (4-1)th auxiliary pixel circuit PCa4-1 in the first row 1R, the description may also be similarly applied to the (1-2)th auxiliary pixel circuit PCa1-2, the (3-2)th auxiliary pixel circuit PCa3-2, and the (4-2)th auxiliary pixel circuit PCa4-2 in the second row 2R illustrated in FIG. 11.

For example, referring to FIG. 11 described above, one (PCa1-1) of the (1-1)th auxiliary pixel circuits PCa1-1 and PCa1-1′ and one (PCa1-2) of the (1-2)th auxiliary pixel circuits PCa1-2 and PCa1-2′ may be electrically connected to a plurality of first auxiliary display elements DEa1 emitting light of the first color (e.g., red).

FIG. 14 is an arrangement diagram illustrating an arrangement relationship of display elements and pixel circuits arranged in a corner display area of a display panel according to an embodiment. Particularly, FIG. 14 illustrates the arrangement relationship of auxiliary display elements and auxiliary pixel circuits in a third row 3R of FIG. 11.

Referring to FIG. 14, a (1-1)th auxiliary pixel circuit PCa1-1′, a (3-1)th auxiliary pixel circuit PCa3-1′, and a (4-1)th auxiliary pixel circuit PCa4-1′ in the third row 3R may be sequentially arranged in the third direction DR3.

A first auxiliary display element DEa1′ may emit light of a first color (e.g., red) and may be electrically connected to the (1-1)th auxiliary pixel circuit PCa1-1′. The first auxiliary display element DEa1′ may be connected to the (1-1)th auxiliary pixel circuit PCa1-1′ by a first connection electrode CM1′. The first connection electrode CM1′ may extend over the (3-1)th auxiliary pixel circuit PCa3-1′. The first connection electrode CM1′ may overlap the (1-1)th auxiliary pixel circuit PCa1-1′, the (3-1)th auxiliary pixel circuit PCa3-1′, and the (4-1)th auxiliary pixel circuit PCa4-1′. The first auxiliary display element DEa1′ may overlap the (1-1)th auxiliary pixel circuit PCa1-1′. The first auxiliary display element DEa1′ may implement the first corner pixel PXcr illustrated in FIG. 7 described above.

A second auxiliary display element DEa2′ may emit light of a second color (e.g., green) and may be electrically connected to the (3-1)th auxiliary pixel circuit PCa3-1′. The second auxiliary display element DEa2′ may be connected to the (3-1)th auxiliary pixel circuit PCa3-1′ by a second connection electrode CM2′. The second auxiliary display element DEa2′ may overlap the (1-1)th auxiliary pixel circuit PCa1-1′, the (3-1)th auxiliary pixel circuit PCa3-1′, and the (4-1)th auxiliary pixel circuit PCa4-1′. The second auxiliary display element DEa2′ may implement the second corner pixel PXcg illustrated in FIG. 7 described above.

A third auxiliary display element DEa3′ may emit light of a third color (e.g., blue) and may be electrically connected to the (4-1)th auxiliary pixel circuit PCa4-1′. The third auxiliary display element DEa3′ may be connected to the (4-1)th auxiliary pixel circuit PCa4-1′ by a third connection electrode CM3′. The third connection electrode CM3′ may extend over the (3-1)th auxiliary pixel circuit PCa3-1′. The third connection electrode CM3′ may overlap the (3-1)th auxiliary pixel circuit PCa1-1′, the (3-1)th auxiliary pixel circuit PCa3-1′, and the (4-1)th auxiliary pixel circuit PCa4-1′. The third auxiliary display element DEa3′ may overlap the (4-1)th auxiliary pixel circuit PCa4-1′. The third auxiliary display element DEa3′ may implement the third corner pixel PXcb illustrated in FIG. 7 described above.

Although the description has been made based on the (3-1)th auxiliary pixel circuit PCa1-1′, the (3-1)th auxiliary pixel circuit PCa3-1′, and the (4-1)th auxiliary pixel circuit PCa4-1′ in the third row 3R, the description may also be similarly applied to the (1-2)th auxiliary pixel circuit PCa1-2′, the (3-2)th auxiliary pixel circuit PCa3-2′, and the (4-2)th auxiliary pixel circuit PCa4-2′ in the fourth row 4R illustrated in FIG. 11.

For example, referring to FIG. 11 described above, another (PCa1-1′) of the (1-1)th auxiliary pixel circuits PCa1-1 and PCa1-1′ and another (PCa1-2′) of the (1-2)th auxiliary pixel circuits PCa1-2 and PCa1-2′ may be electrically connected to a plurality of third auxiliary display elements DEa3′ emitting light of the third color (e.g., blue).

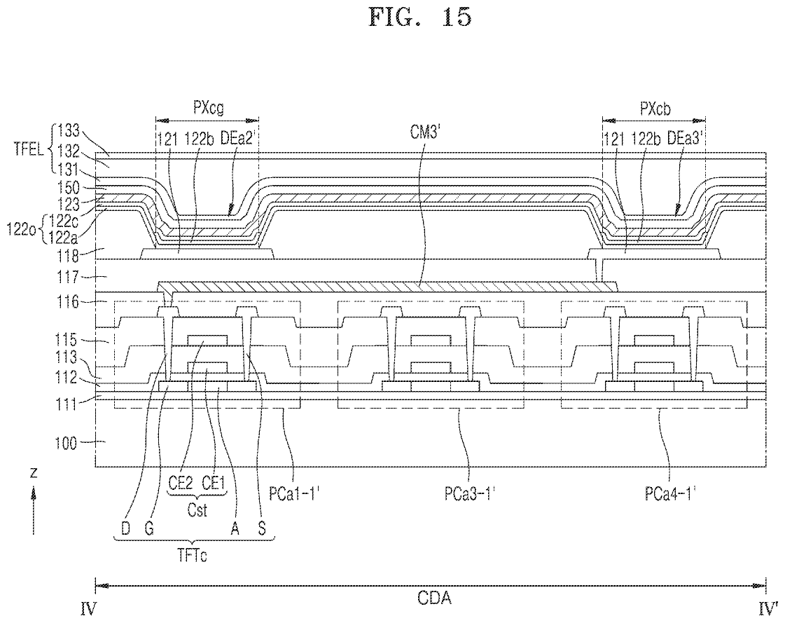

FIG. 15 is an illustrative cross-sectional view of auxiliary pixel circuits and auxiliary display elements taken along line IV-IV′ of FIG. 14. In FIG. 15, like reference numerals as those in FIG. 5 denote like members, and thus redundant descriptions thereof will be omitted for conciseness.

Referring to FIG. 15, the display panel 10 may include a substrate 100, a (1-1)th auxiliary pixel circuit PCa1-1′, disposed on the substrate 100, a (3-1)th auxiliary pixel circuit PCa3-1′, a (4-1)th auxiliary pixel circuit PCa4-1′, a second auxiliary display element DEa2′, and a third auxiliary display element DEa3′. The second auxiliary display element DEa2′ may implement the second corner pixel PXcg, and the third auxiliary display element DEa3′ may implement the third corner pixel PXcb.

In a portion of the corner display area CDA, the (4-1)th auxiliary pixel circuit PCa4-1′ may overlap the third auxiliary display element DEa3′ and may not overlap the first auxiliary display element DEa1′ (see FIG. 14). Also, the (1-1)th auxiliary pixel circuit PCa1-1′ may not overlap the third auxiliary display element DEa3′. Accordingly, the (1-1)th auxiliary pixel circuit PCa1-1′ may be connected through the third connection electrode CM3′ to the third auxiliary display element DEa3′ implementing the third corner pixel PXcb.

The third connection electrode CM3′ may be disposed on the first organic insulating layer 116, and one end of the third connection electrode CM3′ may be connected to the (1-1)th auxiliary pixel circuit PCa1-1′ through a contact hole defined in the first organic insulating layer 116. The other end of the third connection electrode CM3′ may be connected to the pixel electrode 121 of the third auxiliary display element DEa3′ implementing the third corner pixel PXcb. A second organic insulating layer 117 may be arranged between the third connection electrode CM3′ and the pixel electrode 121, and the pixel electrode 121 may be connected to the third connection electrode CM3′ through a contact hole defined in the second organic insulating layer 117. The third connection electrode CM3′ may arranged to overlap the (3-1)th auxiliary pixel circuit PCa3-1′.

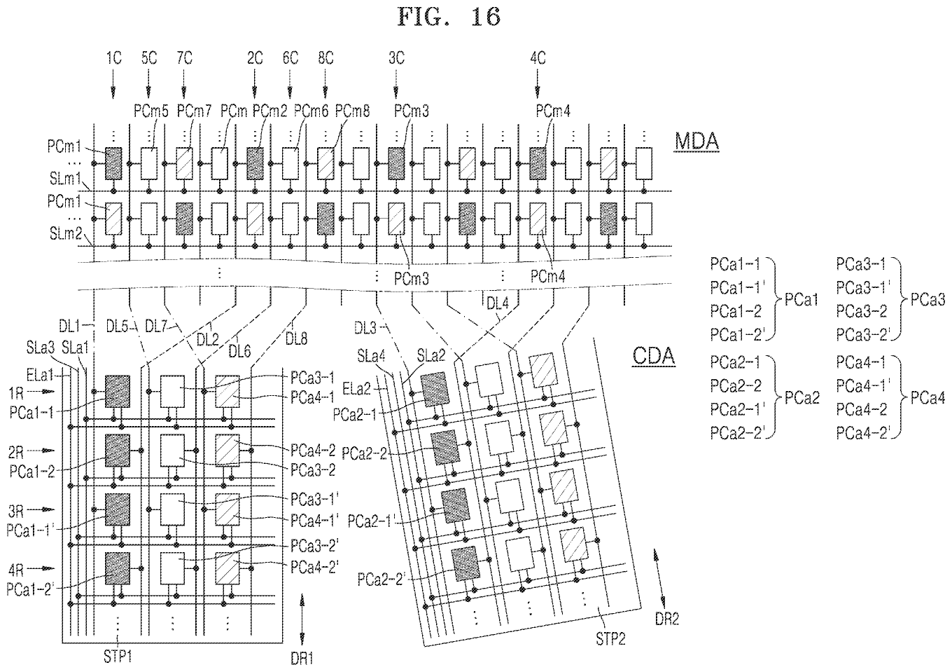

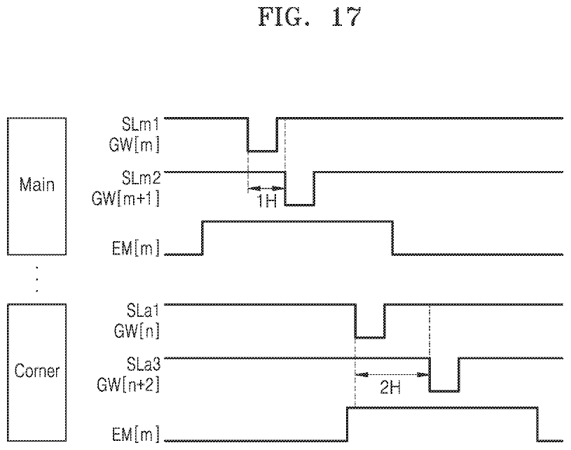

FIG. 16 illustrates a pixel circuit arrangement structure and some signal lines of a main display area and a corner display area of a display panel according to an embodiment, and FIG. 17 is a timing diagram of control signals for operating pixel circuits illustrated in FIG. 16. FIGS. 16 and 17 are respectively modifications of FIGS. 11 and 12, and they are different in scan signal timing. Hereinafter, redundant descriptions thereof will be replaced with those in the description of FIGS. 11 and 12 and differences therebetween will be mainly described.

First, referring to FIG. 17, unlike the illustration in FIG. 12, the first auxiliary scan line SLa1 may be configured to transmit a first auxiliary scan signal GW[n], and the third auxiliary scan line SLa3 may be configured to transmit a third auxiliary scan signal GW[n+2] that is later than the first auxiliary scan signal GW[n] by two horizontal scan periods 2H.

In this case, as illustrated in FIG. 16, the (1-1)th auxiliary pixel circuits PCa1-1 and PCa1-1′ sharing the first data line DL1 with the first main pixel circuits PCm1 of the first column 1C arranged in a PENTILE® matrix structure may be respectively electrically connected to the auxiliary display elements emitting light of the same color. The (1-2)th auxiliary pixel circuits PCa1-2 and PCa1-2′ sharing the second data line DL2 with the second main pixel circuits PCm2 of the second column 2C arranged in a PENTILE® matrix structure may be respectively electrically connected to the auxiliary display elements emitting light of the same color. For example, one (PCa1-1) and another (PCa1-1′) of the (1-1)th auxiliary pixel circuits PCa1-1 and PCa1-1′ and one (PCa1-2) and another (PCa1-2′) of the (1-2)th auxiliary pixel circuits PCa1-2 and PCa1-2′ may be respectively electrically connected to the auxiliary display elements emitting light of the first color (e.g., red).

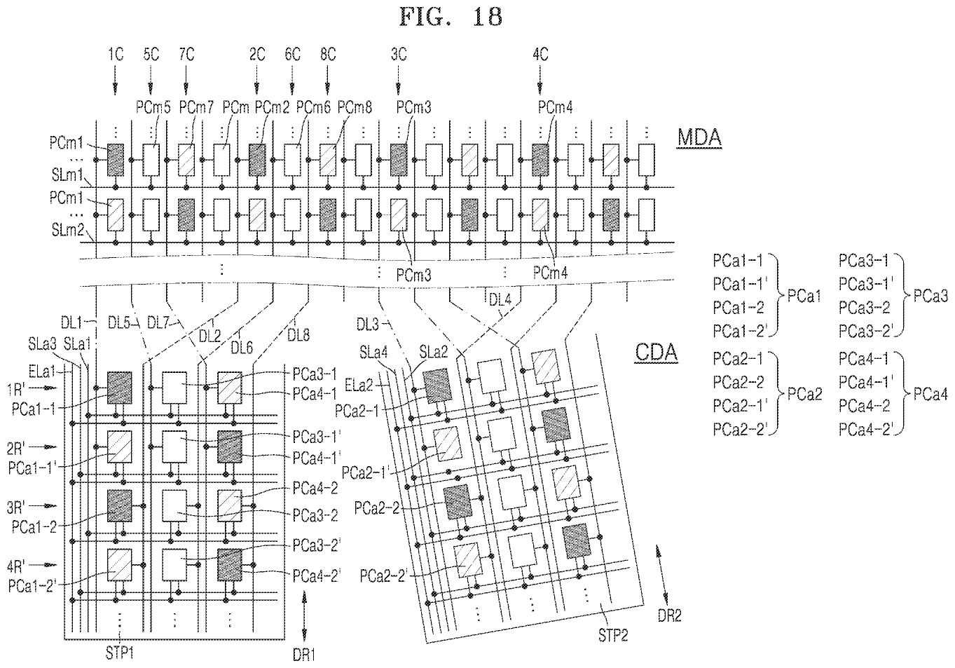

FIG. 18 illustrates a pixel circuit arrangement structure and some signal lines of a main display area and a corner display area of a display panel according to an embodiment. FIG. 18 is a modification of FIG. 11 and may be different from FIG. 11 in terms of the structure of auxiliary pixel circuits. Hereinafter, redundant descriptions thereof will be replaced with those in the description of FIG. 11 and differences therebetween will be mainly described.

Referring to FIG. 18, the (1-1)th auxiliary pixel circuits PCa1-1 and PCa1-1′ and the (1-2)th auxiliary pixel circuits PCa1-2 and PCa1-2′ may not be alternately arranged in the first direction DR1. For example, the (1-1)th auxiliary pixel circuits PCa1-1 and PCa1-1′ may be arranged adjacent to each other, and the (1-2)th auxiliary pixel circuits PCa1-2 and PCa1-2′ may be arranged adjacent to each other.

In this case, the description given above with reference to FIG. 13 may be applied to the auxiliary pixel circuits in a first row 1R′ and a third row 3R′ of FIG. 18, and the description given above with reference to FIG. 14 may be applied to the auxiliary pixel circuits in a second row 2R′ and a fourth row 4R′ of FIG. 18.

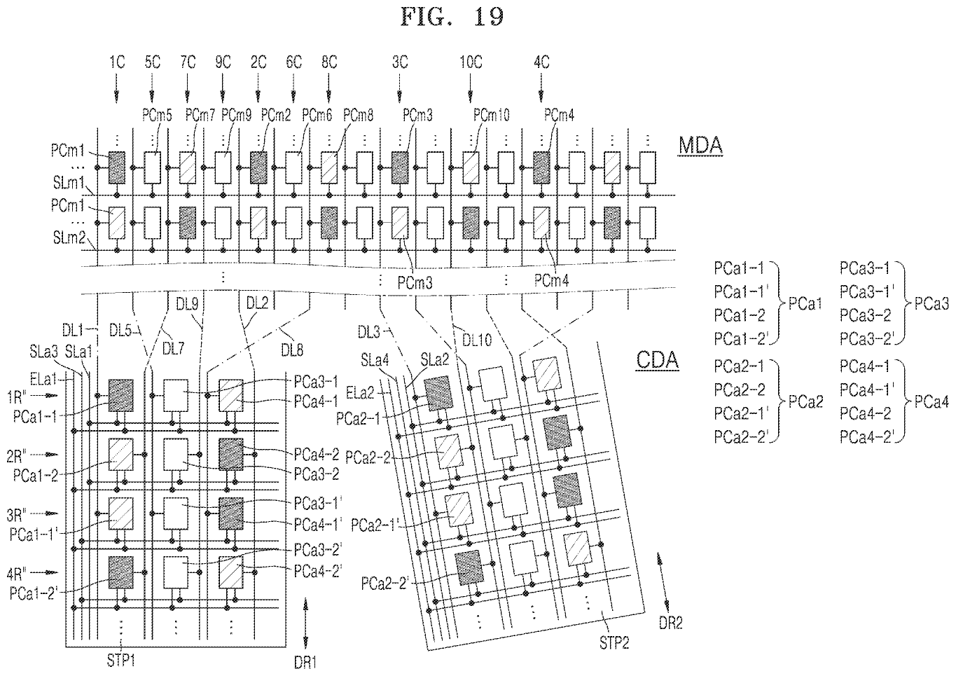

FIG. 19 illustrates a pixel circuit arrangement structure and some signal lines of a main display area and a corner display area of a display panel according to an embodiment. FIG. 19 is a modification of FIG. 11 and may be different from FIG. 11 in terms of the structure of auxiliary pixel circuits. Hereinafter, redundant descriptions thereof will be replaced with those in the description of FIG. 11 and differences therebetween will be mainly described.

Referring to FIG. 19, unlike FIG. 11 described above, the (1-2)th auxiliary pixel circuits PCa1-2 and PCa1-2′ that are some others of the plurality of first auxiliary pixel circuits PCa1 may be connected to the seventh data line DL7. The (3-2)th auxiliary pixel circuits PCa3-2 and PCa3-2′ that are some others of the plurality of third auxiliary pixel circuits PCa3 may be connected to a ninth data line DL9 connected to ninth main pixel circuits PCm9 in a ninth column 9C among the plurality of main pixel circuits PCm. The (4-1)th auxiliary pixel circuits PCa4-1 and PCa4-1′ that are some of the plurality of fourth auxiliary pixel circuits PCa4 may be connected to the eighth data line DL8. The (4-2)th auxiliary pixel circuits PCa4-2 and PCa4-2′ that are some others of the plurality of fourth auxiliary pixel circuits PCa4 may be connected to the second data line DL2.

In this case, the description given above with reference to FIG. 13 may be applied to the auxiliary pixel circuits in a first row 1R″ and a fourth row 4R″ of FIG. 19, and the description given above with reference to FIG. 14 may be applied to the auxiliary pixel circuits in a second row 2R″ and a third row 3R″ of FIG. 19.

Although the first strip portion STP1 has been described as a reference, the strip portion STP2 may also be similarly applied. For example, the (1-2)th auxiliary pixel circuits PCa1-2 and PCa1-2′ that are some others of the plurality of first auxiliary pixel circuits PCa1 may be connected to a tenth data line DL10 connected to tenth main pixel circuits PCm10 in a tenth column 10C among the plurality of main pixel circuits PCm.

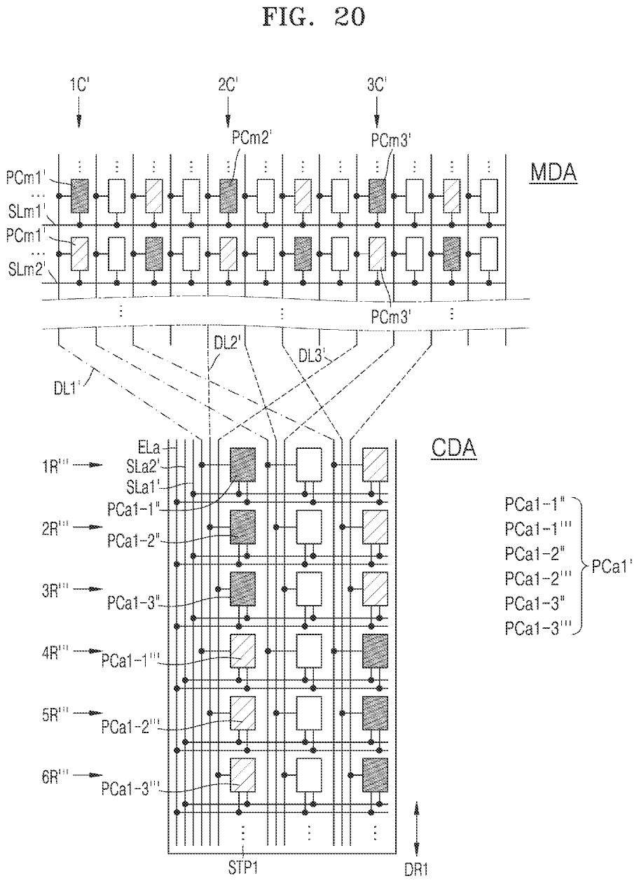

FIG. 20 illustrates a pixel circuit arrangement structure and some signal lines of a main display area and a corner display area of a display panel according to an embodiment.

Referring to FIG. 20, a plurality of main pixel circuits may be arranged in the main display area MDA.

Among the plurality of main pixel circuits, main pixel circuits arranged in the same column may be connected to the same data line. For example, among the plurality of main pixel circuits, first main pixel circuits PCm1′ of a first column 1C′ may be connected to a first data line DL1′, second main pixel circuits PCm2′ of a second column 2C′ may be connected to a second data line DL2′, and third main pixel circuits PCm3′ of a third column 3C′ may be connected to a third data line DL3′.

Among the plurality of main pixel circuits, main pixel circuits arranged in the same row may be connected to the same scan line. For example, among the plurality of main pixel circuits, main pixel circuits arranged in some rows may be connected to a first main scan line SLm1′, and main pixel circuits PCm arranged in some other rows may be connected to a second main scan line SLm2′.

A first strip portion STP1 may be arranged in the corner display area CDA. The first strip portion STP1 may extend from the corner of the main display area MDA in the first direction DR1.

A plurality of first auxiliary pixel circuits PCa1′ may be arranged in a line in the first direction DR1 in the first strip portion STP1.

(1-1)th auxiliary pixel circuits PCa1-1″ and PCa1-1′″ that are some of the plurality of first auxiliary pixel circuits PCa1′, (1-2)th auxiliary pixel circuits PCa1-2″ and PCa1-2′″ that are some others thereof, and (1-3)th auxiliary pixel circuits PCa1-3″ and PCa1-3′″ that are some others thereof may be respectively connected to different data lines. For example, the (1-1)th auxiliary pixel circuits PCa1-1″ and PCa1-1′″ that are some of the plurality of first auxiliary pixel circuits PCa1′ may be connected to the first data line DL1′, the (1-2)th auxiliary pixel circuits PCa1-2″ and PCa1-2′″ that are some others of the plurality of first auxiliary pixel circuits PCa1′ may be connected to the second data line DL2′, and the (1-3)th auxiliary pixel circuits PCa1-3″ and PCa1-3′″ that are some others of the plurality of first auxiliary pixel circuits PCa1′ may be connected to the third data line DL3′.

In an embodiment, as illustrated in FIG. 20, the (1-1)th auxiliary pixel circuits PCa1-1″ and PCa1-1′″, the (1-2)th auxiliary pixel circuits PCa1-2″ and PCa1-2′″, and the (1-3)th auxiliary pixel circuits PCa1-3″ and PCa1-3′″ may be alternately arranged in the first direction DR1.

The (1-1)th auxiliary pixel circuits PCa1-1″ and PCa1-1′″, the (1-2)th auxiliary pixel circuits PCa1-2″ and PCa1-2′″, and the (1-3)th auxiliary pixel circuits PCa1-3″ and PCa1-3′″ may share scan lines with each other. For example, one (PCa1-1″) of the (1-1)th auxiliary pixel circuits PCa1-1″ and PCa1-1′″, one (PCa1-2″) of the (1-2)th auxiliary pixel circuits PCa1-2″ and PCa1-2′″, and one (PCa1-3″) of the (1-3)th auxiliary pixel circuits PCa1-3″ and PCa1-3′″ may be connected to a first auxiliary scan line SLa1′. Another (PCa1-1′″) of the (1-1)th auxiliary pixel circuits PCa1-1″ and PCa1-1′″, another (PCa1-2′″) of the (1-2)th auxiliary pixel circuits PCa1-2″ and PCa1-2′″, and anther (PCa1-3′″) of the (1-3)th auxiliary pixel circuits PCa1-3″ and PCa1-3′″ may be connected to a second auxiliary scan line SLa2′.

In an embodiment, the first auxiliary scan line SLa1′ may be configured to transmit a first auxiliary scan signal, and the second auxiliary scan line SLa2′ may be configured to transmit a second auxiliary scan signal that is later than the first auxiliary scan signal by one horizontal scan period.

In this case, the (1-1)th auxiliary pixel circuits PCa1-1″ and PCa1-1′″ sharing the first data line DL1′ with the first main pixel circuits PCm1′ of the first column 1C′ arranged in a PENTILE® matrix structure may be respectively electrically connected to the auxiliary display elements emitting light of different colors. The (1-2)th auxiliary pixel circuits PCa1-2″ and PCa1-2′″ sharing the second data line DL2′ with the second main pixel circuits PCm2′ of the second column 2C′ arranged in a PENTILE® matrix structure may be respectively electrically connected to the auxiliary display elements emitting light of different colors. The (1-3)th auxiliary pixel circuits PCa1-3″ and PCa1-3′″ sharing the third data line DL3′ with the third main pixel circuits PCm3′ of the third column 3C′ arranged in a PENTILE® matrix structure may be respectively electrically connected to the auxiliary display elements emitting light of different colors. For example, one (PCa1-1″) of the (1-1)th auxiliary pixel circuits PCa1-1″ and PCa1-1′″, one (PCa1-2″) of the (1-2)th auxiliary pixel circuits PCa1-2″ and PCa1-2′″, and one (PCa1-3″) of the (1-3)th auxiliary pixel circuits PCa1-3″ and PCa1-3′″ may be respectively electrically connected to the auxiliary display elements emitting light of the first color (e.g., red), and another (PCa1-1′″) of the (1-1)th auxiliary pixel circuits PCa1-1″ and PCa1-1′″, another (PCa1-2′″) of the (1-2)th auxiliary pixel circuits PCa1-2″ and PCa1-2′″, and another (PCa1-3′″) of the (1-3)th auxiliary pixel circuits PCa1-3″ and PCa1-3′″ may be respectively electrically connected to the auxiliary display elements emitting light of the second color (e.g., blue).

In other words, the description given above with reference to FIG. 13 may be applied to the auxiliary pixel circuits of a first row 1R′″, a second row 2R′″, and a third row 3R′″ of FIG. 20, the description given above with reference to FIG. 14 may be applied to the auxiliary pixel circuits of a fourth row 4R′″, a fifth row 5R′″, and a sixth row 6R′″ of FIG. 20.

In another embodiment, the first auxiliary scan line SLa1′ may be configured to transmit a first auxiliary scan signal, and the second auxiliary scan line SLa2′ may be configured to transmit a second auxiliary scan signal that is later than the first auxiliary scan signal by two horizontal scan periods.

In this case, the (1-1)th auxiliary pixel circuits PCa1-1″ and PCa1-1′″ sharing the first data line DL1′ with the first main pixel circuits PCm1′ of the first column 1C′ arranged in a PENTILE® matrix structure may be respectively electrically connected to the auxiliary display elements emitting light of the same color. The (1-2)th auxiliary pixel circuits PCa1-2″ and PCa1-2′″ sharing the second data line DL2′ with the second main pixel circuits PCm2′ of the second column 2C′ arranged in a PENTILE® matrix structure may be respectively electrically connected to the auxiliary display elements emitting light of the same color. The (1-3)th auxiliary pixel circuits PCa1-3″ and PCa1-3′″ sharing the third data line DL3′ with the third main pixel circuits PCm3′ of the third column 3C′ arranged in a PENTILE® matrix structure may be respectively electrically connected to the auxiliary display elements emitting light of the same color. For example, one (PCa1-1″) and another (PCa1-1′″) of the (1-1)th auxiliary pixel circuits PCa1-1″ and PCa1-1′″, one (PCa1-2″) and another (PCa1-2′″) of the (1-2)th auxiliary pixel circuits PCa1-2″ and PCa1-2′″, and one (PCa1-3″) and another (PCa1-3′″) of the (1-3)th auxiliary pixel circuits PCa1-3″ and PCa1-3′″ may be respectively electrically connected to the auxiliary display elements emitting light of the first color (e.g., red).

In other words, the description given above with reference to FIG. 13 may be applied to the auxiliary pixel circuits of the first row 1R′″, the second row 2R′″, the third row 3R′″, the fourth row 4R′″, the fifth row 5R′″, and the sixth row 6R′″ of FIG. 20.

The (1-1)th auxiliary pixel circuits PCa1-1″ and PCa1-1′″, the (1-2)th auxiliary pixel circuits PCa1-2″ and PCa1-2′″, and the (1-3)th auxiliary pixel circuits PCa1-3″ and PCa1-3′″ may share emission control lines with each other. For example, one (PCa1-1″) and another (PCa1-1′″) of the (1-1)th auxiliary pixel circuits PCa1-1″ and PCa1-1′″, one (PCa1-2″) and another (PCa1-2′″) of the (1-2)th auxiliary pixel circuits PCa1-2″ and PCa1-2′″, and one (PCa1-3″) and another (PCa1-3′″) of the (1-3)th auxiliary pixel circuits PCa1-3″ and PCa1-3′″ may be connected to an auxiliary emission control line ELa.

Although the description has been made based on the first auxiliary pixel circuits PCa1′ arranged in some columns of the first strip portion STP1, the auxiliary pixel circuits arranged in other columns may be similarly applied.

Although only the display panel and the display apparatus have been mainly described above, the disclosure is not limited thereto. For example, a method of manufacturing the display panel and a method of manufacturing the display apparatus may also fall within the scope of the disclosure.

As described above, in the display panel and the display apparatus according to the present embodiments, because a corner display area is included, an image display area may be extended.

Also, in the display panel and the display apparatus according to the present embodiments, because pixel circuits arranged in a corner display area share a scan line with each other, the number of lines arranged in the corner display area may be reduced, which may be advantageous in securing space.

However, the scope of the disclosure is not limited to these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the following claims.

What is claimed is:

1. A display panel comprising:
a substrate including a main display area and a first strip portion extending from the main display area in a first direction;
a plurality of main pixel circuits arranged in a matrix in the main display area;
a plurality of first auxiliary pixel circuits arranged in a line in the first direction in the first strip portion;
a first data line connected to first main pixel circuits in a first column among the plurality of main pixel circuits and (1-1)th auxiliary pixel circuits;
a second data line connected to second main pixel circuits in a second column among the plurality of main pixel circuits and (1-2)th auxiliary pixel circuits; and
a first scan line connected to one of the (1-1)th auxiliary pixel circuits and one of the (1-2)th auxiliary pixel circuits,
wherein the plurality of first auxiliary pixel circuits includes the (1-1)th auxiliary pixel circuits, and
wherein the plurality of first auxiliary pixel circuits includes the (1-2)th auxiliary pixel circuits.

2. The display panel of claim 1, wherein the substrate further includes a second strip portion extending from the main display area in a second direction intersecting with the first direction, and
the display panel further comprises:
a plurality of second auxiliary pixel circuits arranged in a line in the second direction in the second strip portion;
a third data line connected to third main pixel circuits in a third column among the plurality of main pixel circuits and (2-1)th auxiliary pixel circuits;
a fourth data line connected to fourth main pixel circuits in a fourth column among the plurality of main pixel circuits and (2-2)th auxiliary pixel circuits; and
a second scan line connected to one of the (2-1)th auxiliary pixel circuits and one of the (2-2)th auxiliary pixel circuits,
wherein the plurality of second auxiliary pixel circuits includes the (2-1)th auxiliary pixel circuits, and
wherein the plurality of second auxiliary pixel circuits includes the (2-2)th auxiliary pixel circuits.

3. The display panel of claim 2, wherein the first scan line is configured to transmit a first scan signal, and
the second scan line is configured to transmit a second scan signal substantially synchronized with the first scan signal.

4. The display panel of claim 2, wherein the first scan line is configured to transmit a first scan signal, and
the second scan line is configured to transmit a second scan signal that is later than the first scan signal by “n” horizontal scan periods, where “n” is a natural number.

5. The display panel of claim 1, wherein the substrate further includes a corner display area adjacent to a corner of the main display area, and
the first strip portion is arranged in the corner display area and extends from the corner of the main display area in the first direction.

6. The display panel of claim 1, further comprising:
a second scan line connected to another of the (1-1)th auxiliary pixel circuits and another of the (1-2)th auxiliary pixel circuits; and
an emission control line connected to the one and the other of the (1-1)th auxiliary pixel circuits and the one and the other of the (1-2)th auxiliary pixel circuits.

7. The display panel of claim 1, wherein the (1-1)th auxiliary pixel circuits and the (1-2)th auxiliary pixel circuits are alternately arranged in the first direction.

8. The display panel of claim 1, further comprising a second scan line connected to another of the (1-1)th auxiliary pixel circuits and another of the (1-2)th auxiliary pixel circuits,
wherein the first scan line is configured to transmit a first scan signal, and
the second scan line is configured to transmit a second scan signal that is later than the first scan signal by one horizontal scan period.

9. The display panel of claim 8, further comprising:
a plurality of first auxiliary display elements respectively electrically connected to the one of the (1-1)th auxiliary pixel circuits and the one of the (1-2)th auxiliary pixel circuits and emitting light of a first color; and
a plurality of second auxiliary display elements respectively electrically connected to the other of the (1-1)th auxiliary pixel circuits and the other of the (1-2)th auxiliary pixel circuits and emitting light of a second color different from the first color.

10. The display panel of claim 8, further comprising:
a plurality of first auxiliary display elements respectively electrically connected to the one of the (1-1)th auxiliary pixel circuits and the other of the (1-2)th auxiliary pixel circuits and emitting light of a first color; and
a plurality of second auxiliary display elements respectively electrically connected to the other of the (1-1)th auxiliary pixel circuits and the one of the (1-2)th auxiliary pixel circuits and emitting light of a second color different from the first color.

11. The display panel of claim 1, further comprising a second scan line connected to another of the (1-1)th auxiliary pixel circuits and another of the (1-2)th auxiliary pixel circuits,
wherein the first scan line is configured to transmit a first scan signal, and
the second scan line is configured to transmit a second scan signal that is later than the first scan signal by two horizontal scan periods.

12. The display panel of claim 11, further comprising a plurality of auxiliary display elements electrically connected to the one and the other of the (1-1)th auxiliary pixel circuits and the one and the other of the (1-2)th auxiliary pixel circuits and emitting light of a first color.

13. The display panel of claim 1, further comprising:
a first auxiliary display element electrically connected to the one of the (1-1)th auxiliary pixel circuits and emitting light of a first color; and
a second auxiliary display element electrically connected to the one of the (1-2)th auxiliary pixel circuits and emitting light of a second color different from the first color.

14. The display panel of claim 1, further comprising a third data line connected to third main pixel circuits in a third column among the plurality of main pixel circuits and (1-3)th auxiliary pixel circuits that are some others of the plurality of first auxiliary pixel circuits,
wherein the first scan line is connected to one of the (1-3)th auxiliary pixel circuits.

15. A display apparatus comprising:
a display panel comprising a main display area and a first strip portion extending from a corner of the main display area in a first direction and bent with a preset first curvature radius; and
a cover window having a shape corresponding to a shape of the display panel and covering the display panel,
wherein the display panel further comprises:
a plurality of main pixel circuits arranged in a matrix in the main display area;
a plurality of first auxiliary pixel circuits arranged in a line in the first direction in the first strip portion;
a first data line connected to first main pixel circuits in a first column among the plurality of main pixel circuits and (1-1)th auxiliary pixel circuits;
a second data line connected to second main pixel circuits in a second column among the plurality of main pixel circuits and (1-2)th auxiliary pixel circuits; and
a first scan line connected to one of the (1-1)th auxiliary pixel circuits and one of the (1-2)th auxiliary pixel circuits,
wherein the plurality of first auxiliary pixel circuits includes the (1-1)th auxiliary pixel circuits, and
wherein the plurality of first auxiliary pixel circuits includes the (1-2)th auxiliary pixel circuits.

16. The display apparatus of claim 15, wherein the display panel further comprises:
a second strip portion extending from the corner of the main display area in a second direction intersecting with the first direction and bent with a preset second curvature radius;
a plurality of second auxiliary pixel circuits arranged in a line in the second direction in the second strip portion;
a third data line connected to third main pixel circuits in a third column among the plurality of main pixel circuits and (2-1)th auxiliary pixel circuits;
a fourth data line connected to fourth main pixel circuits in a fourth column among the plurality of main pixel circuits and (2-2)th auxiliary pixel circuits; and
a second scan line connected to one of the (2-1)th auxiliary pixel circuits and one of the (2-2)th auxiliary pixel circuits,
wherein the plurality of second auxiliary pixel circuits includes the (2-1)th auxiliary pixel circuits, and
wherein the plurality of second auxiliary pixel circuits includes the (2-2)th auxiliary pixel circuits.

17. The display apparatus of claim 16, wherein the first scan line is configured to transmit a first scan signal, and
the second scan line is configured to transmit a second scan signal substantially synchronized with the first scan signal.

18. The display apparatus of claim 16, wherein the first scan line is configured to transmit a first scan signal, and
the second scan line is configured to transmit a second scan signal that is later than the first scan signal by “n” horizontal scan periods, where “n” is a natural number.

19. The display apparatus of claim 15, wherein the display panel further comprises:
a second scan line connected to another of the (1-1)th auxiliary pixel circuits and another of the (1-2)th auxiliary pixel circuits; and
an emission control line connected to the one and the other of the (1-1)th auxiliary pixel circuits and the one and the other of the (1-2)th auxiliary pixel circuits.

20. The display apparatus of claim 15, wherein the (1-1)th auxiliary pixel circuits and the (1-2)th auxiliary pixel circuits are alternately arranged in the first direction.

21. The display apparatus of claim 15, wherein the display panel further comprises a second scan line connected to another of the (1-1)th auxiliary pixel circuits and another of the (1-2)th auxiliary pixel circuits,
the first scan line is configured to transmit a first scan signal, and
the second scan line is configured to transmit a second scan signal that is later than the first scan signal by one horizontal scan period or two horizontal scan periods.

22. The display apparatus of claim 15, wherein the display panel further comprises:
a first auxiliary display element electrically connected to the one of the (1-1)th auxiliary pixel circuits and emitting light of a first color; and
a second auxiliary display element electrically connected to the one of the (1-2)th auxiliary pixel circuits and emitting light of a second color different from the first color.

23. The display apparatus of claim 15, wherein the display panel further comprises a third data line connected to third main pixel circuits in a third column among the plurality of main pixel circuits and (1-3)th auxiliary pixel circuits that are some others of the plurality of first auxiliary pixel circuits, and
the first scan line is connected to one of the (1-3)th auxiliary pixel circuits.
